(19) United States
(12) Patent Application Publication
(10) Pub. No.: US 2024/0255852 A1
(43) Pub. Date: Aug. 1, 2024

(54) METHOD FOR MANUFACTURING SEMICONDUCTOR SUBSTRATE AND COMPOSITION

(71) Applicant: JSR CORPORATION, Tokyo (JP)

(72) Inventors: Hiroyuki KOMATSU, Tokyo (JP); Masato DOBASHI, Tokyo (JP); Satoshi DEI, Tokyo (JP); Kengo EHARA, Tokyo (JP); Sho YOSHINAKA, Tokyo (JP); Eiji YONEDA, Tokyo (JP); Takashi KATAGIRI, Tokyo (JP)

(73) Assignee: JSR CORPORATION, Tokyo (JP)

(21) Appl. No.: 18/435,001

(22) Filed: Feb. 7, 2024

Related U.S. Application Data
(63) Continuation-in-part of application No. PCT/JP2022/028778, filed on Jul. 26, 2022.

(30) Foreign Application Priority Data
Aug. 10, 2021 (JP) 2021-130632

(51) Int. Cl. G03F 7/11; C08F 12/08; C08F 12/20; C08F 12/24; C08F 12/26; C08F 12/30; C08F 26/06; C09D 125/08; C09D 125/18; C09D 139/04

(52) U.S. Cl. CPC G03F 7/11; C08F 12/08; C08F 12/20; C08F 12/24; C08F 12/26; C08F 12/30; C08F 26/06; C09D 125/08; C09D 125/18; C09D 139/04

(57) ABSTRACT

A method for manufacturing a semiconductor substrate, includes applying a composition for forming a resist underlayer film directly or indirectly to a substrate to form a resist underlayer film. A composition for forming a resist film is applied to the resist underlayer film to form a resist film. The resist film is exposed to radiation. The exposed resist film is developed. The composition for forming a resist underlayer film includes: a polymer having a sulfonic acid ester structure; and a solvent.

### CROSS-REFERENCE TO RELATED APPLICATIONS

The present application is a continuation-in-part application of International Patent Application No. PCT/JP2022/028778 filed Jul. 26, 2022, which claims priority to Japanese Patent Application No. 2021-130632 filed Aug. 10, 2021. The contents of these applications are incorporated herein by reference in their entirety.

### BACKGROUND OF THE DISCLOSURE

### Technical Field

The present disclosure relates to a method for manufacturing a semiconductor substrate and a composition.

### Background Art

A semiconductor device is produced using, for example, a multilayer resist process in which a resist pattern is formed by exposing and developing a resist film laminated on a substrate with a resist underlayer film, such as an organic underlayer film or a silicon-containing film, being interposed between them. In this process, the resist underlayer film is etched using this resist pattern as a mask, and the substrate is further etched using the obtained resist underlayer film pattern as a mask so that a desired pattern is formed on the semiconductor substrate.

In recent years, highly enhanced integration of semiconductor devices has further advanced, and exposure light to be used tends to have a shorter wavelength, as from a KrF excimer laser beam (248 nm) or an ArF excimer laser beam (193 nm) to an extreme ultraviolet ray (13.5 nm; hereinafter also referred to as “EUV”). Various studies have been conducted on compositions for forming a resist underlayer film (see WO 2013/141015 A).

### SUMMARY

According to an aspect of the present disclosure, a method for manufacturing a semiconductor substrate, includes applying a composition for forming a resist underlayer film directly or indirectly to a substrate to form a resist underlayer film. A composition for forming a resist film is applied to the resist underlayer film to form a resist film. The resist film is exposed to radiation. The exposed resist film is developed. The composition for forming a resist underlayer film includes: a polymer having a sulfonic acid ester structure; and a solvent.

According to another aspect of the present disclosure, a composition includes: a polymer having a sulfonic acid ester structure; and a solvent.

### DESCRIPTION OF THE EMBODIMENTS

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

Resist underlayer films are required to have solvent resistance to the solvent of a resist composition and pattern rectangularity of securing rectangularity of a resist pattern by inhibiting trailing of a pattern at a bottom part of a resist film.

The present disclosure relates to, in one embodiment, a method for manufacturing a semiconductor substrate, the method including:
directly or indirectly applying a composition for forming a resist underlayer film to a substrate;
applying a composition for forming a resist film to the resist underlayer film formed by applying the composition for forming a resist underlayer film;
exposing the resist film formed by applying the composition for forming a resist film to radiation; and
developing at least the exposed resist film,
wherein the composition for forming a resist underlayer film contains:
a polymer having a sulfonic acid ester structure (hereinafter also referred to as “polymer [A]”); and
a solvent (hereinafter also referred to as “solvent [C]”).

In another embodiment, the present disclosure relates to a composition for forming a resist underlayer film, including:
a polymer having a sulfonic acid ester structure; and
a solvent.

By the method for manufacturing a semiconductor substrate, it is possible to efficiently manufacture a semiconductor substrate because of using a composition for forming a resist underlayer film capable of forming a resist underlayer film superior in solvent resistance and pattern rectangularity. When the composition for forming a resist underlayer film is used, a film superior in solvent resistance and pattern rectangularity can be formed. Therefore, they can suitably be used for, for example, producing semiconductor devices.

### DESCRIPTION OF THE EMBODIMENTS

Hereinafter, a method for manufacturing a semiconductor substrate and a composition for forming a resist underlayer film according to each embodiment of the present disclosure will be described in detail. Combinations of suitable modes in the embodiments are also preferred.

### <<Method for Manufacturing Semiconductor Substrate>>

The method for manufacturing a semiconductor substrate includes directly or indirectly applying a composition for forming a resist underlayer film to a substrate (this step is hereinafter also referred to as “application step (I)”); applying a composition for forming a resist film to the resist underlayer film formed by applying the composition for forming a resist underlayer film (this step is hereinafter also referred to as “application step (II)”); exposing the resist film formed by applying the composition for forming a resist film to radiation (this step is hereinafter also referred to as “exposure step”); and developing at least the exposed resist film (this step is hereinafter also referred to as “development step”).

By the method for manufacturing a semiconductor substrate, a resist underlayer film superior in solvent resistance and pattern rectangularity can be formed due to the use of a prescribed composition for forming a resist underlayer film in the application step (I), so that a semiconductor substrate having a favorable pattern shape can be manufactured.

Preferably, the method for manufacturing a semiconductor substrate further includes, before the application step (II), heating at 200° C. or higher the resist underlayer film formed by applying the composition for forming a resist underlayer film (hereinafter also referred to as “heating step”).

The method for manufacturing a semiconductor substrate may further include, as necessary, directly or indirectly forming a silicon-containing film on the substrate (this step is hereinafter also referred to as “silicon-containing film formation step”) before the application step (I).

Hereinafter, the composition for forming a resist underlayer film to be used in the method for manufacturing a semiconductor substrate, and the respective steps in the case of including the heating step, which is a preferable step, and the silicon-containing film formation step, which is an optional step, will be described.

### <Composition for Forming Resist Underlayer Film>

The composition for forming a resist underlayer film (this composition is hereinafter also referred to as “composition”) includes a polymer [A] and a solvent [C]. The composition may contain any optional component as long as the effect of the present invention is not impaired. The composition for forming a resist underlayer film can form a resist underlayer film superior in solvent resistance and pattern rectangularity owing to containing the polymer [A] and the solvent [C]. The reason for this is not clear, but can be expected as follows. Since the polymer having a sulfonic acid ester structure in which sulfonic acid is protected (that is, the polymer [A]) is used as a main component of the composition for forming a resist underlayer film, solubility in an organic solvent can be reduced. In addition, a sulfonic acid generated via the decomposition of the sulfonic acid ester in the resist underlayer film supplies an acid to a bottom part of a resist film in the exposed portion in the exposure step, so that solubility in a developer at the bottom part of the resist film is enhanced and pattern rectangularity can be exhibited.

### <Polymer [A]>

The polymer [A] has a sulfonic acid ester structure. The composition may contain one kind or two or more kinds of the polymer [A].

The polymer [A] preferably has at least one selected from the group consisting of a repeating unit represented by formula (1) (hereinafter also referred to as “repeating unit (1)”) and a repeating unit represented by formula (2) (hereinafter also referred to as “repeating unit (2)”). When the polymer [A] has one or both of the repeating unit (1) and the repeating unit (2), a sulfonic acid ester structure can be suitably introduced into the polymer [A].

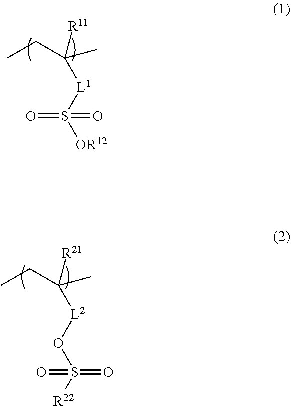

In the formulas (1) and (2), R¹¹ and R²¹ are each independently a hydrogen atom or a substituted or unsubstituted monovalent hydrocarbon group having 1 to 20 carbon atoms. R¹² and R²² are each independently a substituted or unsubstituted monovalent hydrocarbon group having 1 to 20 carbon atoms. L¹ is a single bond or a divalent linking group. L² is a divalent linking group.

As used herein, the “hydrocarbon group” includes a chain hydrocarbon group, an alicyclic hydrocarbon group, and an aromatic hydrocarbon group. The “hydrocarbon group” includes a saturated hydrocarbon group and an unsaturatedhydrocarbon group. The “chain hydrocarbon group” means a hydrocarbon group that contains no cyclic structure and is composed only of a chain structure, and includes both a linear hydrocarbon group and a branched hydrocarbon group. The “alicyclic hydrocarbon group” means a hydrocarbon group that contains only an alicyclic structure as a ring structure and contains no aromatic ring structure, and includes both amonocyclic alicyclic hydrocarbon group and a polycyclic alicyclic hydrocarbon group (however, the alicyclic hydrocarbon group is not required to be composed of only an alicyclic structure, and may contain a chain structure as a part thereof). The “aromatic hydrocarbon group” means a hydrocarbon group containing an aromatic ring structure as a ring structure (however, the aromatic hydrocarbon group is not required to be composed of only an aromatic ring structure, and may contain an alicyclic structure or a chain structure as a part thereof).

Examples of the monovalent chain hydrocarbon group having 1 to 20 carbon atoms include alkyl groups such as a methyl group, an ethyl group, a n-propyl group, an i-propyl group, a n-butyl group, a sec-butyl group, a tert-butyl group, a n-pentyl group, an isopentyl group, and a neopentyl group; alkenyl groups such as an ethenyl group, a propenyl group, and a butenyl group; and alkynyl groups such as an ethynyl group, a propynyl group, and a butynyl group.

Examples of the monovalent alicyclic hydrocarbon group having 3 to 20 carbon atoms include cycloalkyl groups such as a cyclopentyl group and a cyclohexyl group; cycloalkenyl groups such as a cyclopropenyl group, a cyclopentenyl group, and a cyclohexenyl group; bridged cyclic saturated hydrocarbon groups such as a norbornyl group, an adamantyl group, and a tricyclodecyl group; and bridged cyclic unsaturated hydrocarbon groups such as a norbornenyl group and a tricyclodecenyl group.

Examples of the monovalent aromatic hydrocarbon group having 6 to 20 carbon atoms include a phenyl group, a tolyl group, a naphthyl group, an anthracenyl group, and a pyrenyl group.

When R¹¹, R¹², R²¹ and R²² have a substituent, examples of the substituent include monovalent chain hydrocarbon groups having 1 to 10 carbon atoms, halogen atoms such as a fluorine atom, a chlorine atom, a bromine atom, and an iodine atom, alkoxy groups such as a methoxy group, an ethoxy group, and a propoxy group, alkoxycarbonyl groups such as a methoxycarbonyl group and an ethoxycarbonyl group, alkoxycarbonyloxy groups such as a methoxycarbonyloxy group and an ethoxycarbonyloxy group, acyl groups such as a formyl group, an acetyl group, a propionyl group, and a butyryl group, a cyano group, a nitro group, and a hydroxy group.

Among them, a hydrogen atom or a methyl group is preferable as R¹¹ and R²¹ from the viewpoint of the copolymerizability of monomers that afford the repeating units (1) and (2).

On the other hand, as R¹², a monovalent chain hydrocarbon group having 1 to 20 carbon atoms is preferable, an alkyl group having 1 to 20 carbon atoms is more preferable, an alkyl group having 2 to 10 carbon atoms is preferable, and a branched alkyl group having 3 to 10 carbon atoms is still more preferable. These may have a substituent.

As R²², a monovalent chain hydrocarbon group having 1 to 20 carbon atoms or a monovalent aromatic hydrocarbon group having 6 to 20 carbon atoms is preferable, and an alkyl group having 1 to 10 carbon atoms or a phenyl group is more preferable. These may have a substituent.

In the formulas (1) and (2), L¹ and L² are each independently preferably a divalent group having a substituted or unsubstituted divalent hydrocarbon group. Examples of the divalent hydrocarbon group as L¹ and L² include a group obtained by removing one hydrogen atom from the monovalent hydrocarbon group having 1 to 20 carbon atoms as R¹¹. As the substituent in the case where the divalent hydrocarbon group has a substituent, the substituents recited for the cases where R¹¹, R¹², R²¹, and R²² have a substituent can be suitably employed.

The divalent hydrocarbon group in L¹ and L² is preferably a divalent aromatic hydrocarbon group, more preferably a divalent aromatic hydrocarbon group having 6 to 20 carbon atoms, and still more preferably a benzenediyl group or a naphthalenediyl group.

Among them, as L¹ and L², an alkanediyl group obtained by removing one hydrogen atom from an alkyl group having 1 to 10 carbon atoms, a divalent aromatic hydrocarbon group having 6 to 20 carbon atoms, or a combination thereof is preferable, an alkanediyl group having 1 to 5 carbon atoms, a benzenediyl group, a naphthalenediyl group, or a combination thereof is more preferable, and a benzenediyl group or a combination of a benzenediyl group and a methanediyl group is still more preferable. As L², a combination of a benzenediyl group and a methanediyl group is particularly preferable.

R¹² and R²² each independently may be a monovalent hydrocarbon group having 1 to 20 carbon atoms and having a fluorine atom. By introducing a fluorine atom into R¹² and R²², uneven distribution of the repeating units (1) and (2) to the surface side of the resist underlayer film is promoted, and the solvent resistance and the pattern rectangularity of the resist underlayer film can be further improved. As R¹² and R²² each independently, a monovalent fluorinated alkyl group having 1 to 20 carbon atoms is more preferable, a monovalent perfluoroalkyl group having 1 to 10 carbon atoms is more preferable, and a perfluoromethyl group, a perfluoroethyl group, a perfluoropropyl group, or a perfluorobutyl group is still more preferable.

Examples of the repeating unit (1) include repeating units represented by formulas (1-1) to (1-12).

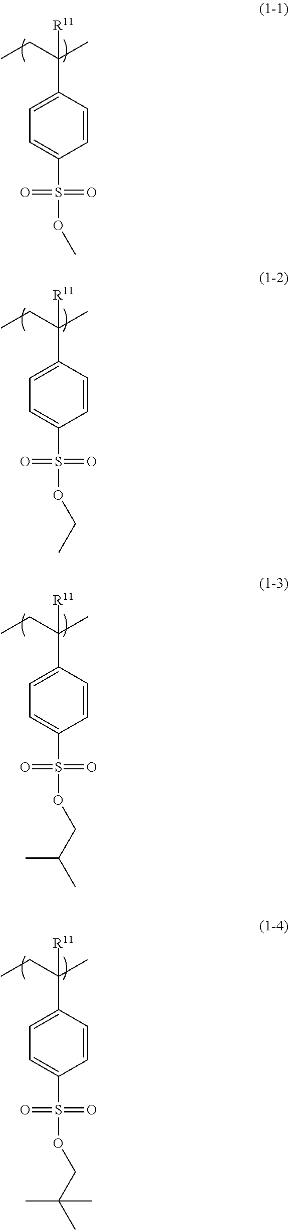

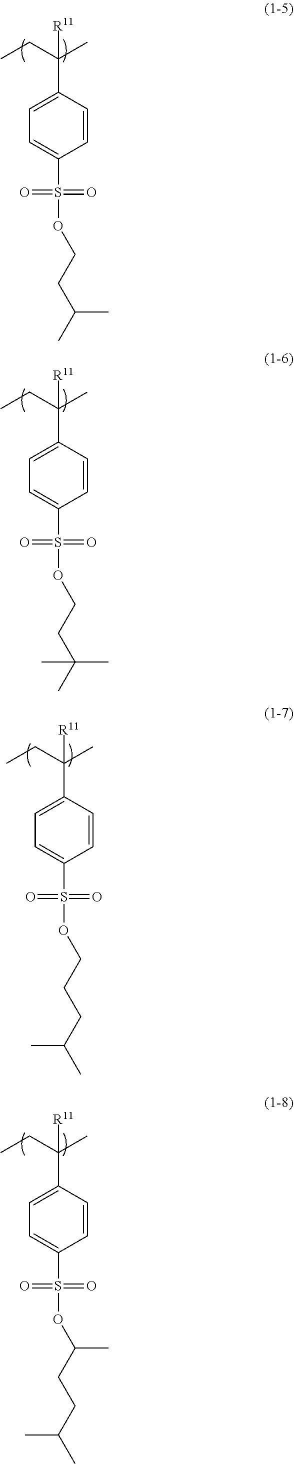

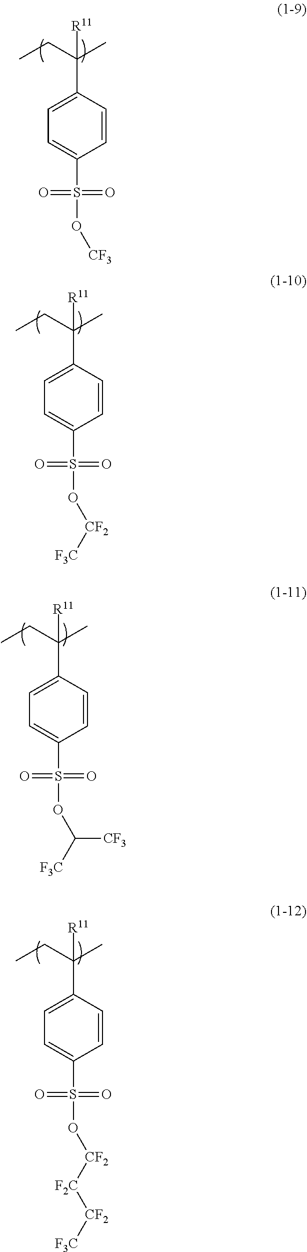

In the formulas (1-1) to (1-12), R¹¹ has the same definition as that in the above formula (1). Among them, the repeating units represented by the formulas (1-4), (1-8), and (1-12) are preferable.

Examples of the repeating unit (2) include repeating units represented by formulas (2-1) to (2-9).

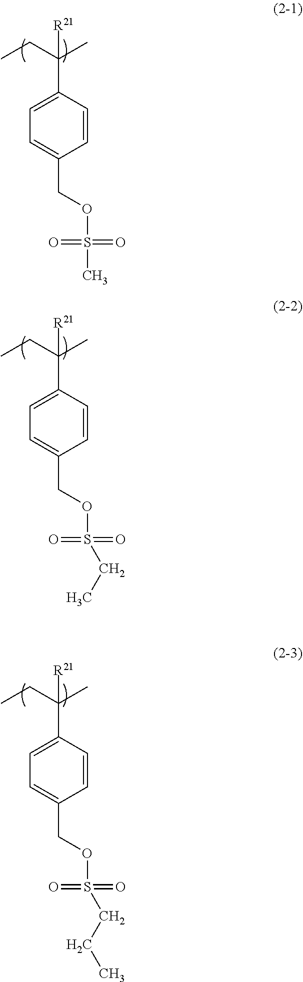

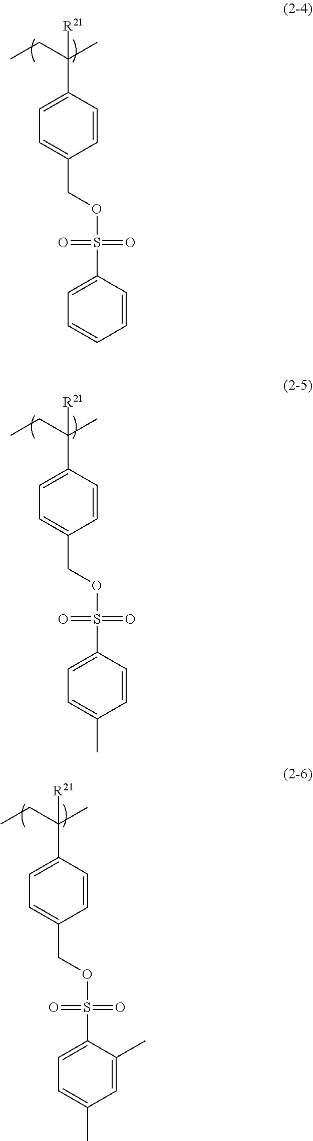

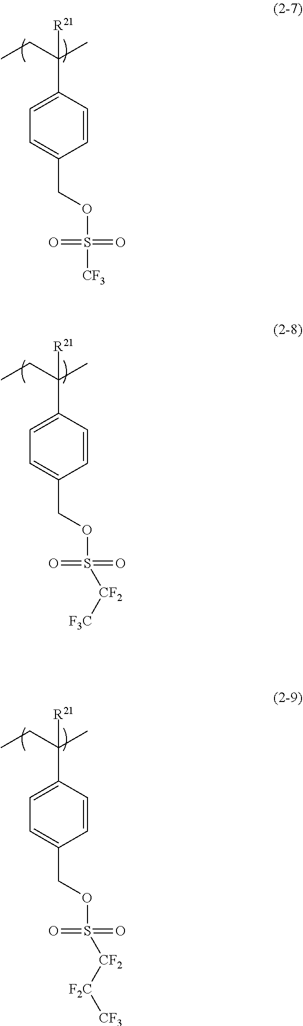

In the formulas (2-1) to (2-9), R²¹ has the same definition as that in the above formula (2). Among them, the repeating units represented by the formulas (2-1), (2-5), and (2-7) are preferable.

The lower limit of the content ratio of the repeating unit (1) or (2) (when both are contained, the total content ratio is taken) accounting for among all the repeating units constituting the polymer [A] is preferably 1 mol %, more preferably 5 mol %, still more preferably 10 mol %, and particularly preferably 20 mol %. The upper limit of the content is preferably 100 mol %, more preferably 70 mol %, still more preferably 60 mol %, and particularly preferably 50 mol %. When the content ratio of the repeating unit (1) or (2) is set within the above range, solvent resistance and pattern rectangularity can be exhibited at a high level.

Preferably, the polymer [A] further has a repeating unit represented by formula (3) (excluding the cases of being the above formulas (1) and (2)) (this unit is hereinafter also referred to as “repeating unit (3)”). The polymer [A] may have one kind or two or more kinds of the repeating unit (3).

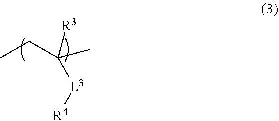

In the formula (3), R³ is a hydrogen atom or a substituted or unsubstituted monovalent hydrocarbon group having 1 to 20 carbon atoms. L³ is a single bond or a divalent linking group. R⁴ is a monovalent organic group having 1 to 20 carbon atoms. The “organic group” refers to a group having at least one carbon atom.

As the monovalent hydrocarbon group having 1 to 20 carbon atoms represented by R³, the groups disclosed as the monovalent hydrocarbon group having 1 to 20 carbon atoms represented by R¹¹, R¹², R²¹, and R²² in the formulas (1) and (2) can be suitably employed.

As the divalent linking group represented by L³, the groups disclosed as the divalent linking groups represented by L¹ and L² in the formulas (1) and (2) can be suitably employed. L³ is preferably a single bond.

Preferable examples of the monovalent organic group having 1 to 20 carbon atoms represented by R⁴ include substituted or unsubstituted monovalent hydrocarbon groups represented by R¹¹, R¹², R²¹, and R²² in the formulas (1) and (2), substituted or unsubstituted monovalent heterocyclic groups, and groups containing —CO—, —CS—, —O—, —S—, —SO₂—, or —NR′—, or a combination of two or more thereof between carbon atoms or at a carbon chain terminal of those groups. R′ is a hydrogen atom or a monovalent hydrocarbon group having 1 to 10 carbon atoms. As the substituted or unsubstituted monovalent hydrocarbon group, a substituted or unsubstituted monovalent aromatic hydrocarbon group is preferable.

Examples of the substituent that substitutes a part or all of the hydrogen atoms of the organic group include groups disclosed as the substituent of the monovalent hydrocarbon groups having 1 to 20 carbon atoms represented by R¹¹, R¹², R²¹, and R²² in the formulas (1) and (2).

Examples of the heterocyclic group include a group obtained by removing one hydrogen atom from an aromatic heterocyclic structure and a group obtained by removing one hydrogen atom from an alicyclic heterocyclic structure. A 5-membered aromatic structure having aromaticity due to introducing a heteroatom is also included in the heterocyclic structure. Examples of the heteroatom include an oxygen atom, a nitrogen atom, and a sulfur atom.

Examples of the aromatic heterocyclic structure include:
oxygen atom-containing aromatic heterocyclic structures such as furan, pyran, benzofuran, and benzopyran;
nitrogen atom-containing aromatic heterocyclic structures such as pyrrole, imidazole, pyridine, pyrimidine, pyrazine, indole, quinoline, isoquinoline, acridine, phenazine, and carbazole;
sulfur atom-containing aromatic heterocyclic structures such as thiophene; and
aromatic heterocyclic structures containing a plurality of heteroatoms such as thiazole, benzothiazole, thiazine, and oxazine.

Examples of the alicyclic heterocyclic structure include:
oxygen atom-containing alicyclic heterocyclic structures such as oxirane, oxetane, tetrahydrofuran, tetrahydropyran, dioxolane and dioxane;
nitrogen atom-containing alicyclic heterocyclic structures such as aziridine, pyrrolidine, pyrazolidine, piperidine and piperazine;
sulfur atom-containing alicyclic heterocyclic structures such as thietane, thiolane, and thiane;
alicyclic heterocyclic structures containing a plurality of heteroatoms such as oxazoline, morpholine, oxathiolane, oxazine, and thiomorpholine; and structures in which an alicyclic heterocyclic structure and an aromatic ring structure are combined such as benzoxazine.

Examples of the cyclic structure include a lactone structure, a cyclic carbonate structure, a sultone structure, and a structure containing a cyclic acetal.

Examples of the repeating unit represented by the formula (3) include repeating units represented by formulas (3-1) to (3-10).

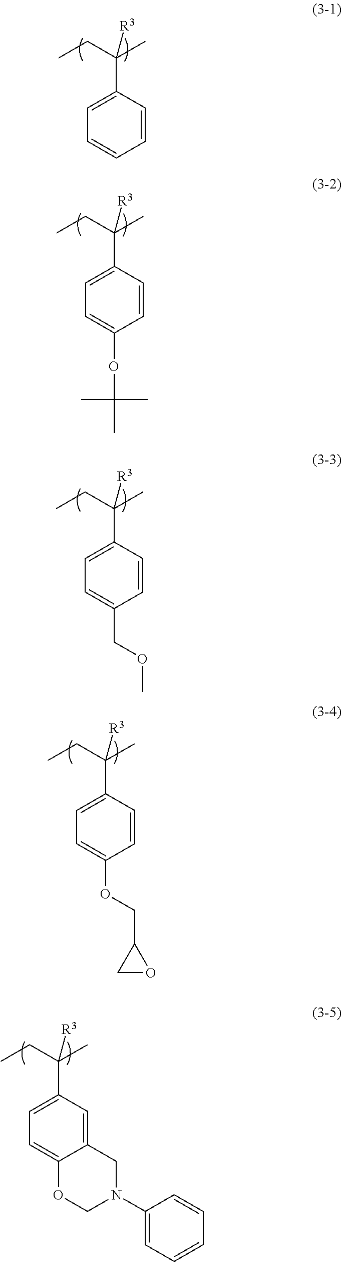

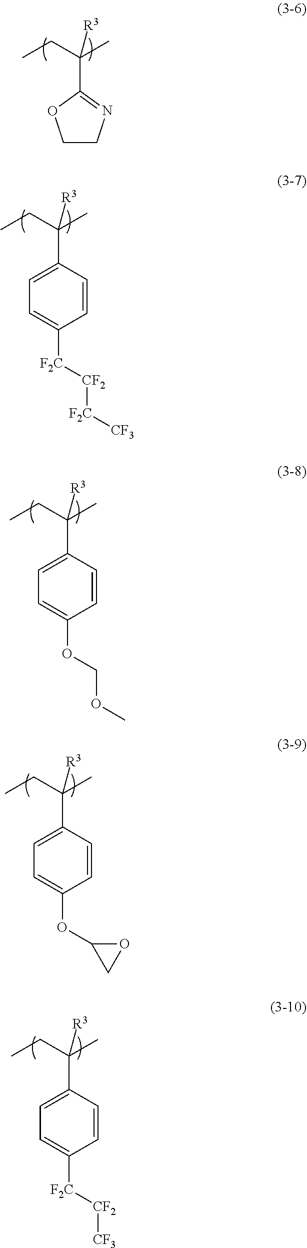

In the formulas (3-1) to (3-10), R³ has the same definition as that in the above formula (3). Among them, the repeating units represented by the formulas (3-1) to (3-7) are preferable.

When the polymer [A] has the repeating unit (3), the lower limit of the content ratio of the repeating unit (3) (when a plurality of types thereof are contained, the total content ratio is taken) accounting for among all the repeating units constituting the polymer [A] is preferably 10 mol %, more preferably 20 mol %, still more preferably 30 mol %, and particularly preferably 40 mol %. The upper limit of the content is preferably 95 mol %, more preferably 90 mol %, still more preferably 80 mol %, and particularly preferably 70 mol %. When the content ratio of the repeating unit (3) is set within the above range, solvent resistance and pattern rectangularity can be exhibited at a high level.

The polymer [A] may have a repeating unit derived from maleic acid, maleic anhydride, a maleimide derivative, or the like as another repeating unit.

The lower limit of the weight average molecular weight of the polymer [A] is preferably 500, more preferably 1000, still more preferably 1500, and particularly preferably 2000. The upper limit of the molecular weight is preferably 10000, more preferably 9000, still more preferably 8000, and particularly preferably 7000. The weight average molecular weight is measured as described in EXAMPLES.

The lower limit of the content ratio of the polymer [A] in the composition for forming a resist underlayer film is preferably 1% by mass, more preferably 2% by mass, still more preferably 3% by mass, and particularly preferably 4% by mass in the total mass of the polymer [A] and the solvent [C]. The upper limit of the content ratio is preferably 20% by mass, more preferably 15% by mass, still more preferably 12% by mass, and particularly preferably 10% by mass in the total mass of the polymer [A] and the solvent [C].

The lower limit of the content ratio of the polymer [A] accounting for among the components other than the solvent [C] in the composition for forming a resist underlayer film is preferably 10% by mass, more preferably 20% by mass, and still more preferably 30% by mass. The upper limit of the content ratio is preferably 100% by mass, more preferably 90% by mass, and still more preferably 80% by mass.

### [Method for Synthesizing Polymer [A] ]

The polymer [A] can be synthesized by performing radical polymerization, ion polymerization, polycondensation, polyaddition, addition condensation, or the like depending on the type of the monomer. For example, when the polymer [A] is synthesized by radical polymerization, the polymer can be synthesized by polymerizing monomers which will afford respective structural units using a radical polymerization initiator of the like in an appropriate solvent.

Examples of the radical polymerization initiator include azo radical initiators, such as azobisisobutyronitrile (AIBN), 2,2′-azobis(4-methoxy-2,4-dimethylvaleronitrile), 2,2′-azobis(2-cyclopropylpropionitrile), 2,2′-azobis(2,4-dimethylvaleronitrile), dimethyl 2,2′-azobisisobutyrate and dimethyl-2,2′-azobis(2-methylpropionate); and peroxide radical initiators, such as benzoyl peroxide, t-butyl hydroperoxide and cumene hydroperoxide. These radical initiators may be used singly, or two or more of them may be used in combination.

As the solvent to be used for the polymerization, the solvent [C] described later can be suitably employed. The solvents to be used for the polymerization may be used singly, or two or more solvents may be used in combination.

The reaction temperature in the polymerization is usually 40° C. to 150° C., and preferably 50° C. to 120° C. The reaction time is usually 1 hour to 48 hours, and preferably 1 hour to 24 hours.

### [Other Polymers]

The composition for forming a resist underlayer film may contain a polymer not containing the repeating units (1) and (2) (hereinafter also referred to as “polymer [B]”) in addition to the polymer [A]. The composition may contain one kind or two or more kinds of the polymer [B].

The polymer [B] preferably has a repeating unit represented by formula (4) (this unit is hereinafter also referred to as “repeating unit (4)”):

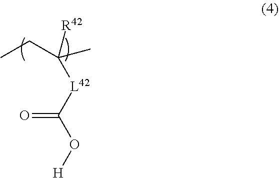

in the formula (4), R⁴² is a hydrogen atom or a substituted or unsubstituted monovalent hydrocarbon group having 1 to 20 carbon atoms; and L⁴² is a single bond or a divalent linking group.

In the formula (4), as the substituted or unsubstituted monovalent hydrocarbon group having 1 to 20 carbon atoms represented by R⁴², the groups disclosed as the substituted or unsubstituted monovalent hydrocarbon group having 1 to 20 carbon atoms represented by R¹¹ in the formula (1) can be suitably employed.

In the formula (4), as the divalent linking group represented by L⁴², the groups disclosed as the divalent linking group represented by L¹ in the formula (1) can be suitably employed. As L⁴², a single bond, an alkanediyl group obtained by removing one hydrogen atom from an alkyl group having 1 to 10 carbon atoms, a cycloalkylene group obtained by removing one hydrogen atom from a cycloalkyl group having 5 to 10 carbon atoms, an arylene group obtained by removing one hydrogen atom from a monovalent aromatic hydrocarbon group having 6 to 20 carbon atoms, a carbonyl group, an oxygen atom, or a combination thereof is a preferable, and a single bond, an alkanediyl group having 1 to 5 carbon atoms, a cycloalkylene group having 5 to 7 carbon atoms, a phenylene group, a carbonyl group, an oxygen atom, or a combination thereof is more preferable.

Examples of the repeating unit represented by the formula (4) include repeating units represented by formulas (4-1) to (4-8).

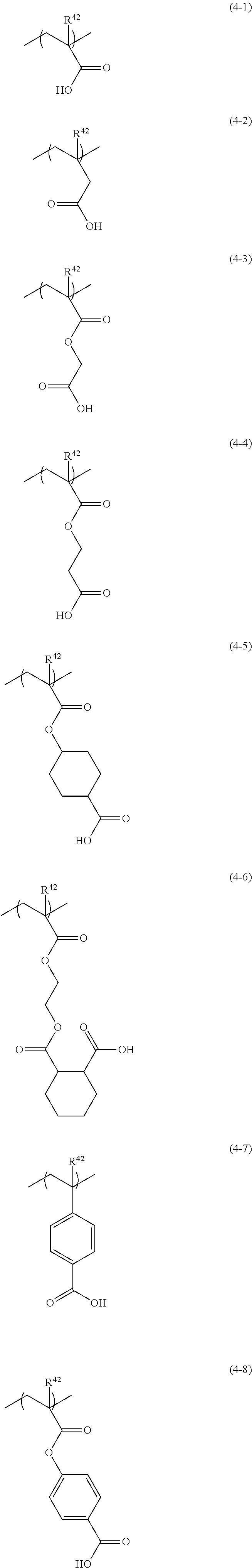

In the formulas (4-1) to (4-8), R⁴² has the same definition as that in the above formula (4).

When the polymer [B] has the repeating unit (4), the lower limit of the content ratio of the repeating unit (4) accounting for among all the repeating units constituting the polymer [B] is preferably 10 mol %, more preferably 30 mol %, and still more preferably 50 mol %. The upper limit of the content is preferably 99 mol %, more preferably 90 mol %, and still more preferably 85 mol %.

The polymer [B] may have a repeating unit represented by formula (5) (excluding the case of being the formula (4)) (this unit is hereinafter also referred to as “repeating unit (5)”):

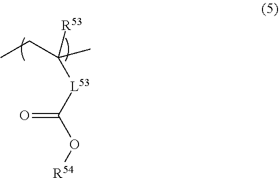

in the formula (5), R⁵³ is a hydrogen atom or a substituted or unsubstituted monovalent hydrocarbon group having 1 to 20 carbon atoms; L⁵³ is a single bond or a divalent linking group; and R⁵⁴ is a substituted or unsubstituted monovalent hydrocarbon group having 1 to 20 carbon atoms.

In the formula (5), as each of the substituted or unsubstituted monovalent hydrocarbon groups having 1 to 20 carbon atoms represented by R⁵³ and R⁵⁴, the groups disclosed as the substituted or unsubstituted monovalent hydrocarbon group having 1 to 20 carbon atoms represented by R¹¹ in the formula (1) can be suitably employed. A hydrogen atom or a methyl group is preferable as R⁵³ from the viewpoint of the copolymerizability of a monomer that affords the repeating unit (5). A monovalent chain hydrocarbon group having 1 to 15 carbon atoms is preferable as R⁵4, and a monovalent branched alkyl group having 1 to 10 carbon atoms is more preferable. When R⁵³ or R⁵⁴ have a substituent, examples of the substituent preferably include the substituents that can be possessed by R¹¹ of the above formula (1).

In the formula (5), as the divalent linking group represented by L⁵³, the groups disclosed as the divalent linking group represented by L¹ in the formula (1) can be suitably employed. As L⁵³, a single bond, an alkanediyl group obtained by removing one hydrogen atom from an alkyl group having 1 to 10 carbon atoms, a cycloalkylene group obtained by removing one hydrogen atom from a cycloalkyl group having 5 to 10 carbon atoms, a carbonyl group, an oxygen atom, or a combination thereof is a preferable, a single bond, an alkanediyl group having 1 to 5 carbon atoms, a cycloalkylene group having 5 to 7 carbon atoms, a carbonyl group, an oxygen atom, or a combination thereof is more preferable, and a single bond is still more preferable.

Examples of the repeating unit represented by the formula (5) include repeating units represented by formulas (5-1) to (5-14).

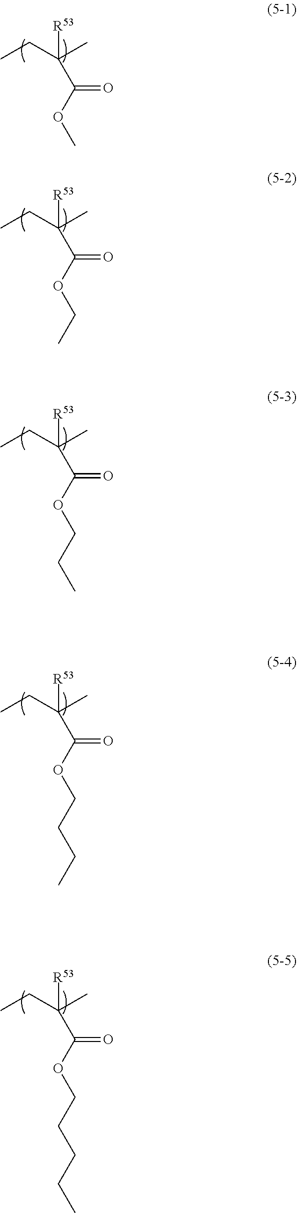

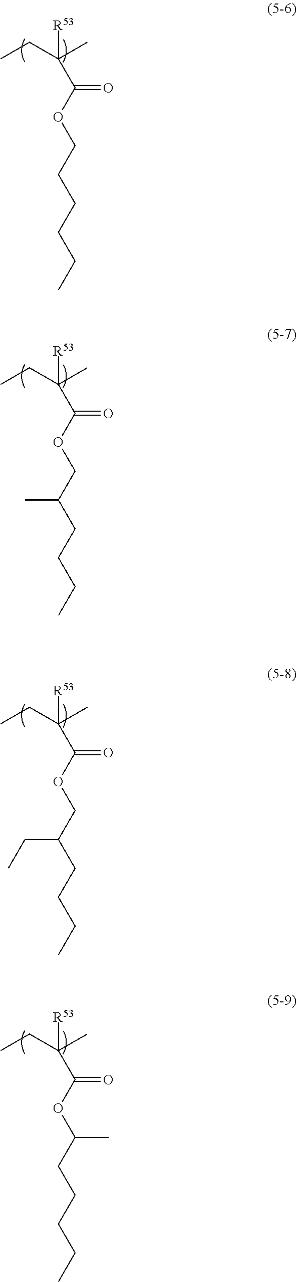

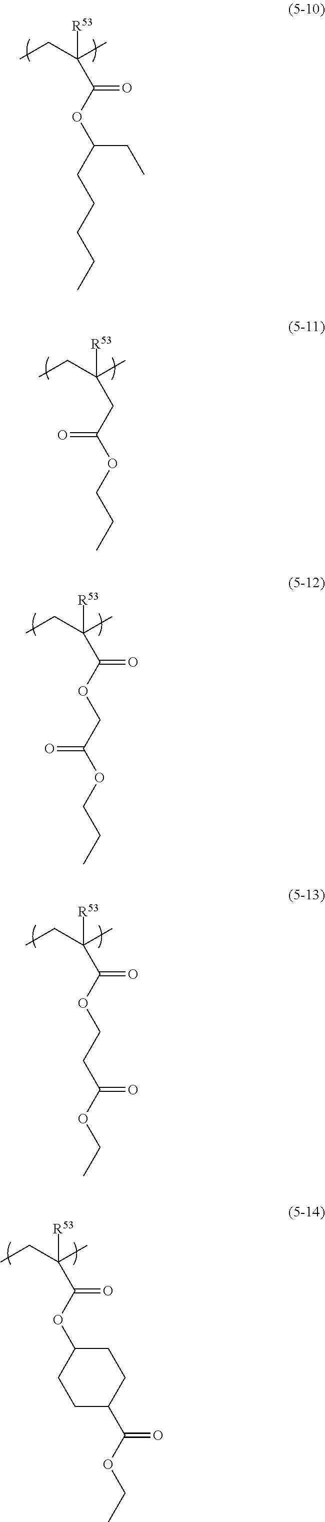

In the formulas (5-1) to (5-14), R⁵³ has the same definition as that in the above formula (5).

When the polymer [B] has the repeating unit (5), the lower limit of the content ratio of the repeating unit (5) accounting for among all the repeating units constituting the polymer [B] is preferably 1 mol %, more preferably 5 mol %, and still more preferably 10 mol %. The upper limit of the content is preferably 60 mol %, more preferably 40 mol %, and still more preferably 30 mol %.

The polymer [B] may have a repeating unit represented by formula (6) (excluding the cases of being the formulas (4) and (5)) (this unit is hereinafter also referred to as “repeating unit (6)”)

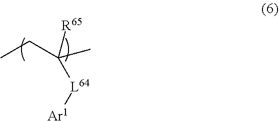

in the formula (6), R⁶⁵ is a hydrogen atom or a substituted or unsubstituted monovalent hydrocarbon group having 1 to 20 carbon atoms; L⁶⁴ is a single bond or a divalent linking group; and Ar¹ is a monovalent group having an aromatic ring having 6 to 20 ring members.

In the present specification, the term “ring members” refers to the number of atoms constituting the ring. For example, a biphenyl ring has 12 ring members, a naphthalene ring has 10 ring members, and a fluorene ring has 13 ring members.

In the formula (6), as the substituted or unsubstituted monovalent hydrocarbon group having 1 to 20 carbon atoms represented by R⁶⁵, the groups disclosed as the substituted or unsubstituted monovalent hydrocarbon group having 1 to 20 carbon atoms represented by R¹¹ in the formula (1) can be suitably employed. A hydrogen atom or a methyl group is preferable as R⁶⁵ from the viewpoint of the copolymerizability of a monomer that affords the repeating unit (6). When R⁶⁵ has a substituent, examples of the substituent suitably include the substituents that can be possessed by R¹¹ of the above formula (1).

In the formula (6), as the divalent linking group represented by L⁶⁴, the groups disclosed as the divalent linking group represented by L¹ in the formula (1) can be suitably employed. As L⁶⁴, a single bond, an alkanediyl group obtained by removing one hydrogen atom from an alkyl group having 1 to 10 carbon atoms, a cycloalkylene group obtained by removing one hydrogen atom from a cycloalkyl group having 5 to 10 carbon atoms, a carbonyl group, an oxygen atom, or a combination thereof is a preferable, a single bond, an alkanediyl group having 1 to 5 carbon atoms, a cycloalkylene group having 5 to 7 carbon atoms, a carbonyl group, an oxygen atom, or a combination thereof is more preferable, and a single bond is still more preferable.

In the above formula (6), examples of the aromatic ring having 6 to 20 ring numbers as Ar¹ include aromatic hydrocarbon rings such as a benzene ring, a naphthalene ring, an anthracene ring, an indene ring, and a pyrene ring, aromatic heterocyclic rings such as a pyridine ring, a pyrazine ring, a pyrimidine ring, a pyridazine ring, and a triazine ring, or a combination thereof. The aromatic ring of the Ar¹ is preferably at least one aromatic hydrocarbon ring selected from the group consisting of a benzene ring, a naphthalene ring, an anthracene ring, a phenalene ring, a phenanthrene ring, a pyrene ring, a fluorene ring, a perylene ring, and a coronene ring, and more preferably a benzene ring, a naphthalene ring, or a pyrene ring.

In the formula (6), suitable examples of the monovalent group having an aromatic ring having 6 to 20 ring members represented by Ar¹ include a group obtained by removing one hydrogen atom from the aromatic ring having 6 to 20 ring members in the Ar¹.

Examples of the repeating unit represented by the formula (6) include repeating units represented by formulas (6-1) to (6-8).

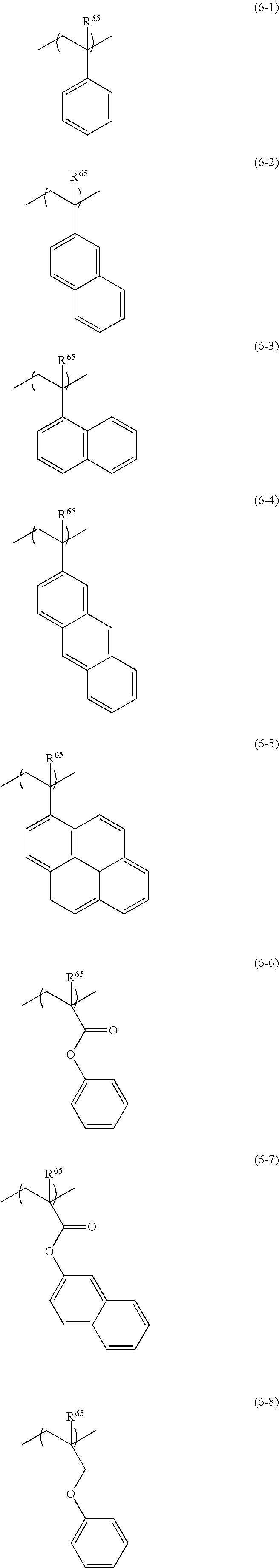

In the formulas (6-1) to (6-8), R⁶⁵ has the same definition as that in the above formula (6). Among them, the repeating unit represented by the formula (6-1) is preferable.

When the polymer [B] has the repeating unit (6), the lower limit of the content ratio of the repeating unit (6) accounting for among all the repeating units constituting the polymer [B] is preferably 5 mol %, more preferably 10 mol %, and still more preferably 20 mol. The upper limit of the content is preferably 80 mol, more preferably 70 mol, and still more preferably 50 mol %.

The polymer [B] may have a repeating unit represented by formula (7) (hereinafter also referred to as “repeating unit (7)”) together with or in place of the repeating units (4) to (6):

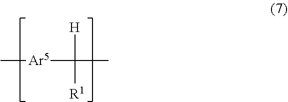

in the formula (7), Ar⁵ is a divalent group having an aromatic ring having 5 to 40 ring atoms; and R′ is a hydrogen atom or a monovalent organic group having 1 to 60 carbon atoms.

Examples of the aromatic ring having 5 to 40 ring members in Ar⁵ include aromatic rings obtained by extending the aromatic rings having 6 to 20 ring members in Ar¹ to 5 to 40 ring members. Suitable examples of the divalent group having an aromatic ring having 5 to 40 ring atoms represented by Ar⁵ include groups obtained by removing two hydrogen atoms from the aromatic ring having 5 to 40 ring atoms.

Examples of the monovalent organic group having 1 to 60 carbon atoms represented by R′ include a monovalent hydrocarbon group having 1 to 60 carbon atoms, a group containing a divalent heteroatom-containing group between two carbon atoms of the foregoing hydrocarbon group, a group obtained by substituting a part or all of the hydrogen atoms of the foregoing hydrocarbon group with a monovalent heteroatom-containing group, and a combination thereof.

As the monovalent hydrocarbon group having 1 to 60 carbon atoms, groups obtained by extending the monovalent hydrocarbon groups having 1 to 20 carbon atoms in R¹¹ of the formula (1) to 1 to 60 carbon atoms can be suitably employed.

Examples of heteroatoms that constitute divalent or monovalent heteroatom-containing groups include an oxygen atom, a nitrogen atom, a sulfur atom, a phosphorus atom, a silicon atom, and halogen atoms. Examples of the halogen atoms include a fluorine atom, a chlorine atom, a bromine atom, and an iodine atom.

Examples of the divalent heteroatom-containing group include —CO—, —CS—, —NH—, —O—, —S—, and groups obtained by combining them.

Examples of the monovalent heteroatom-containing group include a hydroxy group, a sulfanyl group, a cyano group, a nitro group, and halogen atoms.

Examples of the repeating unit represented by the formula (7) include repeating units represented by formulas (7-1) to (7-3).

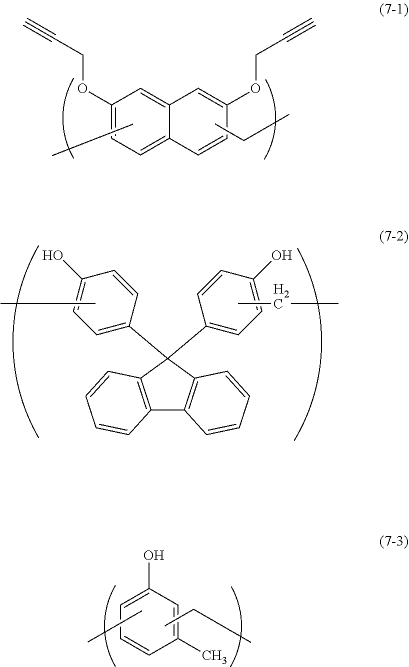

The lower limit of the weight average molecular weight of the polymer [B] is preferably 500, more preferably 1000, still more preferably 2000, and particularly preferably 3000. The upper limit of the molecular weight is preferably 10000, more preferably 9000, still more preferably 8000, and particularly preferably 7000. The weight average molecular weight is measured as described in EXAMPLES.

When the composition for forming a resist underlayer film contains the polymer [B], the lower limit of the content ratio of the polymer [B] is preferably 10% by mass, more preferably 20% by mass, still more preferably 30% by mass, and particularly preferably 40% by mass in the total mass of the polymer [A] and the polymer [B]. The upper limit of the content ratio is preferably 90% by mass, more preferably 80% by mass, still more preferably 70% by mass, and particularly preferably 60% by mass in the total mass of the polymer [A] and the solvent [C].

### [Method for Synthesizing Polymer [B]]

The polymer [B] can be synthesized in the same manner as the method for synthesizing the polymer [A]. For example, when the polymer [B] is synthesized by radical polymerization, the polymer can be synthesized by polymerizing monomers which will afford respective structural units using a radical polymerization initiator of the like in an appropriate solvent. Alternatively, a novolac-type polymer [B] can be produced by acid addition condensation of an aromatic compound that affords Ar⁵ of the above formula (7) with an aldehyde or an aldehyde derivative as a precursor that affords R¹.

### <Solvent [C]>

The solvent [C] is not particularly limited as long as it can dissolve or disperse the compound [A], the acid generating agent [B], and optional components contained as necessary.

Examples of the solvent [C] include a hydrocarbon-based solvent, an ester-based solvent, an alcohol-based solvent, a ketone-based solvent, an ether-based solvent, and a nitrogen-containing solvent. The solvent [C] may be used singly or two or more kinds thereof may be used in combination.

Examples of the hydrocarbon-based solvent include aliphatic hydrocarbon-based solvents such as n-pentane, n-hexane, and cyclohexane, and aromatic hydrocarbon-based solvents such as benzene, toluene, and xylene.

Examples of the ester-based solvent include carbonate-based solvents such as diethyl carbonate, acetic acid monoacetate ester-based solvents such as methyl acetate and ethyl acetate, lactone-based solvents such as γ-butyrolactone, polyhydric alcohol partial ether carboxylate-based solvents such as diethylene glycol monomethyl ether acetate and propylene glycol monomethyl ether acetate, and lactate ester-based solvents such as methyl lactate and ethyl lactate.

Examples of the alcohol-based solvent include monoalcohol-based solvents such as methanol, ethanol, n-propanol, 4-methyl-2-pentanol and 2,2-dimethyl-1-propanol, and polyhydric alcohol-based solvents such as ethylene glycol and 1,2-propylene glycol.

Examples of the ketone-based solvent include chain ketone-based solvents such as methyl ethyl ketone and methyl isobutyl ketone, 2-heptanone, and cyclic ketone-based solvents such as cyclohexanone.

Examples of the ether-based solvent include chain ether-based solvents such as n-butyl ether, cyclic ether-based solvents such as tetrahydrofuran, polyhydric alcohol ether-based solvents such as propylene glycol dimethyl ether, and polyhydric alcohol partial ether-based solvents such as diethylene glycol monomethyl ether, propylene glycol monomethyl ether.

Examples of the nitrogen-containing solvent include chain nitrogen-containing solvents such as N,N-dimethylacetamide, and cyclic nitrogen-containing solvents such as N-methylpyrrolidone.

As the solvent [C], alcohol-based solvents, ether-based solvents, and ester-based solvents are preferable, monoalcohol-based solvents, polyhydric alcohol partial ether-based solvents, polyhydric alcohol partial ether carboxylate-based solvents, and lactic acid ester-based solvents are more preferable, and 4-methyl-2-pentanol, 2,2-dimethyl-1-propanol, propylene glycol monomethyl ether, propylene glycol monomethyl ether acetate, and ethyl lactate are still more preferable.

The lower limit of the content ratio of the solvent [C] in the composition for forming a resist underlayer film is preferably 50% by mass, more preferably 60% by mass, and still more preferably 70% by mass. The upper limit of the content ratio is preferably 99.9% by mass, more preferably 99% by mass, and still more preferably 95% by mass.

### (Optional Component)

The composition for forming a resist underlayer film may include an optional component as long as the effect of the composition is not impaired. Examples of the optional component include a crosslinking agent, an acid generating agent, a dehydrating agent, an acid diffusion controlling agent, and a surfactant. The optional component may be used singly or two or more kinds thereof may be used in combination.

### (Crosslinking Agent [D])

The type of the crosslinking agent [D] is not particularly limited, and a publicly known crosslinking agent can be freely selected and used. Preferably, at least one selected from polyfunctional (meth)acrylates, cyclic ether-containing compounds, glycolurils, diisocyanates, melamines, benzoguanamines, polynuclear phenols, polyfunctional thiol compounds, polysulfide compounds, and sulfide compounds is preferably used as the crosslinking agent. When the composition contains the crosslinking agent [D], crosslinking of the polymer [A] and, as necessary, the polymer [B] can be advanced, and the solvent resistance of the resist underlayer film can be improved.

The polyfunctional (meth)acrylate is not particularly limited as long as it is a compound having two or more (meth)acryloyl groups, and examples thereof include a polyfunctional (meth)acrylate obtained by reacting an aliphatic polyhydroxy compound with (meth)acrylic acid, a caprolactone-modified polyfunctional (meth)acrylate, an alkylene oxide-modified polyfunctional (meth)acrylate, a polyfunctional urethane (meth)acrylate obtained by reacting a (meth)acrylate having a hydroxy group with a polyfunctional isocyanate, and a polyfunctional (meth)acrylate having a carboxyl group obtained by reacting a (meth)acrylate having a hydroxy group with an acid anhydride.

Specifically, examples of the polyfunctional (meth)acrylate include trimethylolpropane tri(meth)acrylate, ditrimethylolpropane tetra(meth)acrylate, pentaerythritol tri(meth)acrylate, pentaerythritol tetra(meth)acrylate, dipentaerythritol penta(meth)acrylate, dipentaerythritol hexa(meth)acrylate, glycerin tri(meth)acrylate, tris(2-hydroxyethyl)isocyanurate tri(meth)acrylate, ethylene glycol di(meth)acrylate, 1,3-butanediol di(meth)acrylate, 1,4-butanediol di(meth)acrylate, 1,6-hexanediol di(meth)acrylate, neopentyl glycol di(meth)acrylate, diethylene glycol di(meth)acrylate, triethylene glycol di(meth)acrylate, dipropylene glycol di(meth)acrylate, and bis(2-hydroxyethyl)isocyanurate di(meth)acrylate.

Examples of the cyclic ether-containing compound include oxiranyl group-containing compounds such as 1,6-hexanediol diglycidyl ether, 3′,4′-epoxycyclohexenylmethyl-3′,4′-epoxycyclohexenecarboxylat e, vinylcyclohexene monooxide 1,2-epoxy-4-vinylcyclohexene, and 1,2:8,9 diepoxylimonene; and oxetanyl group-containing compounds such as 3-ethyl-3-hydroxymethyloxetane, 2-ethylhexyloxetane, xylylene bisoxetane, and 3-ethyl-3{[(3-ethyloxetan-3-yl)methoxy]methyl}oxetane. These cyclic ether-containing compounds can be used singly, or two or more types thereof may be used in combination.

Examples of the glycolurils include compounds derived from tetramethylolglycoluril, tetramethoxyglycoluril, tetramethoxymethylglycoluril, and tetramethylolglycoluril through methoxymethylation of 1 to 4 methylol groups thereof, or mixtures of the compounds, compounds derived from tetramethylolglycoluril through acyloxymethylation of 1 to 4 methylol groups thereof, and glycidylglycolurils.

Examples of the glycidylglycolurils include 1-glycidylglycoluril, 1,3-diglycidylglycoluril, 1,4-diglycidylglycoluril, 1,6-diglycidylglycoluril, 1,3,4-triglycidylglycoluril, 1,3,4,6-tetraglycidylglycoluril, 1-glycidyl-3a-methylglycoluril, 1-glycidyl-6a-methylglycoluril, 1,3-diglycidyl-3a-methylglycoluril, 1,4-diglycidyl-3a-methylglycoluril, 1,6-diglycidyl-3a-methylglycoluril, 1,3,4-triglycidyl-3a-methylglycoluril, 1,3,4-triglycidyl-6a-methyglycoluril, 1,3,4,6-tetraglycidyl-3a-methylglycoluril, 1-glycidyl-3a,6a-dimethylglycoluril, 1,3-diglycidyl-3a,6a-dimethylglycoluril, 1,4-diglycidyl-3a,6a-dimethylglycoluril, 1,6-diglycidyl-3a,6a-dimethylglycoluril, 1,3,4-triglycidyl-3a,6a-dimethylglycoluril, 1,3,4,6-tetraglycidyl-3a,6a-dimethylglycoluril, 1-glycidyl-3a,6a-diphenylglycoluril, 1,3-diglycidyl-3a,6a-diphenylglycoluril, 1,4-diglycidyl-3a,6a-diphenylglycoluril, 1,6-diglycidyl-3a,6a-diphenylglycoluril, 1,3,4-triglycidyl-3a,6a-diphenylglycoluril, and 1,3,4,6-tetraglycidyl-3a,6a-diphenylglycoluril. These glycolurils can be used singly, or two or more types thereof may be used in combination.

Examples of the diisocyanates include 2,3-tolylenediisocyanate, 2,4-tolylenediisocyanate, 3,4-tolylenediisocyanate, 3,5-tolylenediisocyanate, 4,4′-diphenylmethanediisocyanate, hexamethylenediisocyanate, and 1,4-cyclohexanediisocyanate.

Examples of the melamines include melamine, monomethylolmelamine, dimethylolmelamine, trimethylolmelamine, tetramethylolmelamine, pentamethylolmelamine, hexamethylolmelamine, monobutylolmelamine, dibutylolmelamine, tributylolmelamine, tetrabutylolmelamine, pentabutylolmelamine, and hexabthyolmelamine, and alkylated derivatives of these methylolmelamines or butylolmelamines. These melamines can be used singly, or two or more types thereof may be used in combination.

Examples of the benzoguanamines include benzoguanamine in which amino groups are modified with four alkoxymethyl groups (alkoxymethylol groups) (tetraalkoxymethylbenzoguanamines (tetraalkoxymethylolbenzoguanamines)), such as tetramethoxymethylbenzoguanamine;
benzoguanamine in which amino groups are modified with four groups in total of alkoxymethyl groups (especially, methoxymethyl groups) and hydroxymethyl groups (methylol groups);
benzoguanamine having amino groups modified with three or less alkoxymethyl groups (especially, methoxymethyl groups); and
benzoguanamine in which amino groups are modified with three or less groups in total of alkoxymethyl groups (especially, methoxymethyl groups) and hydroxymethyl groups.

These benzoguanamines can be used singly, or two or more types thereof may be used in combination.

Examples of the polynuclear phenols include binuclear phenols such as 4,4′-biphenyldiol, 4,4′-methylenebisphenol, 4,4′-ethylidenebisphenol, and bisphenol A; trinuclear phenols such as 4,4′,4‘ ’-methylidenetrisphenol, 4,4′-(1-(4-(1-(4-hydroxyphenyl)-1-methylethyl)phenyl)ethyliden e)bisphenol, and 4,4′-(1-(4-(1-(4-hydroxy-3,5-bis(methoxymethyl)phenyl)-1-methy lethyl)phenyl)ethylidene)bis(2,6-bis(methoxymethyl)phenol); and polyphenols such as novolac. These polynuclear phenols can be used singly, or two or more types thereof may be used in combination.

The polyfunctional thiol compound is a compound having two or more mercapto groups in one molecule, and specifically, examples thereof include compounds having two mercapto groups such as 1,2-ethanedithiol, 1,3-propanedithiol, 1,4-butanedithiol, 2,3-butanedithiol, 1,5-pentanedithiol, 1,6-hexanedithiol, 1,8-octanedithiol, 1,9-nonanedithiol, 2,3-dimercapto-1-propanol, dithioerythritol, 2,3-dimercaptosuccinic acid, 1,2-benzenedithiol, 1,2-benzenedimethanethiol, 1,3-benzenedithiol, 1,3-benzenedimethanethiol, 1,4-benzenedimethanethiol, 3,4-dimercaptooluene, 4-chloro-1,3-benzenedithiol, 2,4,6-trimethyl-1,3-benzenedimethanethiol, 4,4′-thiodiphenol, 2-hexylamino-4,6-dimercapto-1,3,5-triazine, 2-diethylamino-4,6-dimercapto-1,3,5-triazine, 2-cyclohexylamino-4,6-dimercapto-1,3,5-triazine, 2-di-n-butylamino-4,6-dimercapto-1,3,5-triazine, ethylene glycol bis(3-mercaptopropionate), butanediol bisthioglycolate, ethylene glycol bisthioglycolate, 2,5-dimercapto-1,3,4-thiadiazole, 2,2′-(ethylenedithio)diethanethiol, and 2,2-bis(2-hydroxy-3-mercaptopropoxyphenylpropane); compounds having three mercapto groups such as 1,2,6-hexanetrioltrithioglycolate, 1,3,5-trithiocyanuric acid, trimethylolpropane tris(3-mercaptopropionate), and trimethylolpropane tristhioglycolate; and compounds having 4 or more mercapto groups such as pentaerythritol tetrakis(2-mercaptoacetate), pentaerythritol tetrakis(2-mercaptopropionate) pentaerythritol tetrakis(3-mercaptopropionate), pentaerythritol tetrakis(3-mercaptobutyrate), and 1,3,5-tris(3-mercaptobutyryloxyethyl)-1,3,5-triazine-2,4,6(1H,3H,5H)-trione. These polyfunctional thiol compounds can be used singly, or two or more types thereof may be used in combination.

When the composition for forming a resist underlayer film contains the crosslinking agent [D], the lower limit of the content of the crosslinking agent [D] is preferably 10 parts by mass, more preferably 20 parts by mass, and still more preferably 30 parts by mass per 100 parts by mass of the polymer [A] or per 100 parts by mass in total of the polymers [A] and [B]. The upper limit of the content is preferably 300 parts by mass, more preferably 250 parts by mass, and still more preferably 200 parts by mass.

### [Method for Preparing Composition for Forming Resist Underlayer Film]

The composition for forming a resist underlayer film can be prepared by mixing the polymer [A], the solvent [C] and, as necessary, an optional component in a prescribed ratio and preferably filtering the resulting mixture through a membrane filter having a pore size of 0.5 μm or less, or the like.

### [Silicon-Containing Film Forming Step]

In this step performed before the application step (I), a silicon-containing film is formed directly or indirectly on a substrate.

Examples of the substrate include metallic or semimetallic substrates such as a silicon substrate, an aluminum substrate, a nickel substrate, a chromium substrate, a molybdenum substrate, a tungsten substrate, a copper substrate, a tantalum substrate, and a titanium substrate. Among them, a silicon substrate is preferred. The substrate may be a substrate having a silicon nitride film, an alumina film, a silicon dioxide film, a tantalum nitride film, or a titanium nitride film formed thereon.

The silicon-containing film can be formed by, for example, application, chemical vapor deposition (CVD), atomic layer deposition (ALD), or the like of a composition for forming a silicon-containing film. Examples of a method for forming a silicon-containing film by application of a composition for forming a silicon-containing film include a method in which a coating film formed by applying a composition for forming a silicon-containing film directly or indirectly to the substrate is cured by exposure and/or heating. As a commercially available product of the composition for forming a silicon-containing film, for example, “NFC SOG01”, “NFC SOGO4”, or “NFC SOG080” (all manufactured by JSR Corporation) can be used. By chemical vapor deposition (CVD) or atomic layer deposition (ALD), a silicon oxide film, a silicon nitride film, a silicon oxynitride film, or an amorphous silicon film can be formed.

Examples of the radiation to be used for the exposure include electromagnetic waves such as visible rays, ultraviolet rays, far ultraviolet rays, X-rays, and y-rays and corpuscular rays such as electron beam, molecular beams, and ion beams.

The lower limit of the temperature in heating the coating film is preferably 90° C., more preferably 150° C., and still more preferably 200° C. The upper limit of the temperature is preferably 550° C., more preferably 450° C., and still more preferably 300° C.

The lower limit of the average thickness of the silicon-containing film is preferably 1 nm, more preferably 10 nm, and still more preferably 20 nm. The upper limit is preferably 20,000 nm, more preferably 1,000 nm, and still more preferably 100 nm. The average thickness of the silicon-containing film can be measured in the same manner as for the average thickness of the resist underlayer film.

Examples of a case where the silicon-containing film is formed indirectly on the substrate include a case where the silicon-containing film is formed on a low dielectric insulating film or an organic underlayer film formed on the substrate.

### [Application Step (I)]

In this step, a composition for forming a resist underlayer film is applied to the silicon-containing film formed on the substrate. The method of the application of the composition for forming a resist underlayer film is not particularly limited, and the application can be performed by an appropriate method such as spin coating, cast coating, or roll coating. As a result, a coating film is formed, and volatilization of the solvent [B] or the like occurs, so that a resist underlayer film is formed.

The lower limit of the average thickness of the resist underlayer film to be formed is preferably 0.5 nm, more preferably 1 nm, and still more preferably 2 nm. The upper limit of the average thickness is preferably 50 nm, more preferably 20 nm, still more preferably 10 nm, and particularly preferably 7 nm. The average thickness is measured as described in Examples.

When the composition for forming a resist underlayer film is applied directly to the substrate, the silicon-containing film formation step may be omitted.

### [Heating Step]

Next, the resist underlayer film formed by the application step (I) is heated. Deprotection of the sulfonic acid ester structure in the polymer [A] is promoted by the heating of the resist underlayer film. This step is performed before the application step (II).

The heating of the coating film may be performed either in the air atmosphere or in a nitrogen atmosphere. The lower limit of the heating temperature is just required to be 200° C., but is preferably 210° C., more preferably 220° C., and still more preferably 230° C. The upper limit of the heating temperature is preferably 400° C., more preferably 350° C., and still more preferably 280° C. The lower limit of the heating time is preferably 15 seconds, and more preferably 30 seconds. The upper limit of the time is preferably 800 seconds, more preferably 400 seconds, and still more preferably 200 seconds.

### [Application Step (II)]

In this step, a composition for forming a resist film is formed on the resist underlayer film formed by the step of applying a composition for forming a resist underlayer film. The method of applying the composition for forming a resist film is not particularly limited, and examples thereof include a spin coating method.

Describing this step more in detail, for example, a resist composition is applied such that a resist film formed comes to have a prescribed thickness, and then prebaking (hereinafter also referred to as “PB”) is performed to volatilize the solvent in the coating film. As a result, a resist film is formed.

The PB temperature and the PB time may be appropriately determined according to the type and the like of the composition for forming a resist film to be used. The lower limit of the PB temperature is preferably 30° C., and more preferably 50° C. The upper limit of the PB temperature is preferably 200° C., and more preferably 150° C. The lower limit of the PB time is preferably 10 seconds, and more preferably 30 seconds. The upper limit of the PB time is preferably 600 seconds, and more preferably 300 seconds.

As the composition for forming a resist film used in this step, a so-called positive-type composition for forming a resist film for alkali development is preferably used. Such a composition for forming a resist film is preferably a positive-type composition for forming a resist film containing, for example, a resin having an acid-dissociable group and a radiation-sensitive acid generator and intended for exposure to ArF excimer laser light (for ArF exposure) or exposure to extreme ultraviolet rays (for EUV exposure).

### [Exposure Step]

In this step, a resist film formed in the step of applying a composition for forming a resist film is exposed to radiation. This step causes a difference in solubility in a basic solution as a developer between an exposed portion and an unexposed portion in the resist film. More specifically, the solubility of the exposed portion in the basic solution in the resist film is increased.

Radiation to be used for the exposure can be appropriately selected according to the type or the like of the composition for forming a resist film to be used. Examples thereof include electromagnetic rays such as visible rays, ultraviolet rays, far-ultraviolet, X-rays, and γ-rays and corpuscular rays such as electron beam, molecular beams, and ion beams. Among these, far-ultraviolet rays are preferable, and KrF excimer laser light (wavelength: 248 nm), ArFexcimer laser light (wavelength: 193 nm), F₂ excimer laser light (wavelength: 157 nm), Kr₂ excimer laser light (wavelength: 147 nm), ArKr excimer laser light (wavelength: 134 nm) or extreme ultraviolet rays (wavelength: 13.5 nm, etc., also referred to as “EUV”) are more preferred, and ArF excimer laser light or EUV is even more preferred. Further, the exposure conditions can be determined as appropriate depending on the type of resist film forming composition used.

In this step, post exposure baking (hereinafter, also referred to as “PEB”) can be performed after the exposure in order to improve the resist film performance such as resolution, pattern profile, and developability. The PEB temperature and the PEB time may be appropriately determined according to the type and the like of the composition for forming a resist film to be used. The lower limit of the PEB temperature is preferably 50° C., and more preferably 70° C. The upper limit of the PEB temperature is preferably 200° C., and more preferably 150° C. The lower limit of the PEB time is preferably 10 seconds, and more preferably 30 seconds. The upper limit of the PEB time is preferably 600 seconds, and more preferably 300 seconds.

### [Development Step]

In this step, at least the exposed resist film is developed. This step is preferably alkali development in which the developer to be used is a basic solution. Since there is a difference in solubility in a basic solution as a developer between the exposed portion and the unexposed portion in the resist film as a result of the exposure step, the exposed portion having a relatively high solubility in the basic solution is removed via alkali development and a resist pattern is formed.

In the step of developing the exposed resist film, it is preferable to further develop a part of the resist underlayer film. When the resist underlayer film contains a polymer containing a sulfonic acid group, the solubility thereof in a basic solution as a developer is enhanced, so that the resist underlayer film can be removed together with the resist film in the step of developing the resist film. The resist underlayer film may be developed only partially in the thickness direction from the outermost surface of the resist underlayer film, but is more preferably developed entirely in the thickness direction (that is, the entire resist underlayer film is removed in the exposed portion). The part of the resist underlayer film to be developed may be a part of the resist underlayer film in the planar direction. By developing the resist film with a basic solution and subsequently developing the resist underlayer film, an etching step of the resist underlayer film, which is conventionally necessary, can be omitted, and a good resist pattern can be efficiently formed through the reduction of the number of steps and the inhibition of the influence on other films and the like.

The basic solution for the alkali development is not particularly limited, and a publicly known basic solution can be used. Examples of the basic solution for the alkali development include, in the alkaline development, an alkaline aqueous solution obtained by dissolving at least one alkaline compound such as sodium hydroxide, potassium hydroxide, sodium carbonate, sodium silicate, sodium metasilicate, ammonia water, ethylamine, n-propylamine, diethylamine, di-n-propylamine, triethylamine, methyldiethylamine, ethyldimethylamine, triethanolamine, tetramethyl ammonium hydroxide (TMAH), pyrrole, piperidine, choline, 1,8-diazabicyclo-[5.4.0]-7-undecene, and 1,5-diazabicyclo-[4.3.0]-5-nonene. Among them, the aqueous TMAH solution is preferable, and a 2.38% by mass aqueous TMAH solution is more preferable.

Examples of a developer in the case of performing organic solvent development include the same as those disclosed as the examples of the solvent [C] described above.

In this step, washing and/or drying may be performed after the development.

### [Etching Step]

In this step, etching is performed using the resist pattern (and the resist underlayer film pattern) as a mask. The number of times of the etching may be once. Alternatively, etching may be performed a plurality of times, that is, etching may be sequentially performed using a pattern obtained by etching as a mask. From the viewpoint of obtaining a pattern having a favorable shape, etching is preferably performed a plurality of times. When performed a plurality of times, etching is performed to the silicon-containing film, and the substrate sequentially in order. Examples of an etching method include dry etching and wet etching. Dry etching is preferable from the viewpoint of achieving a favorable shape of the pattern of the substrate. In the dry etching, for example, gas plasma such as oxygen plasma is used. As a result of the etching, a semiconductor substrate having a prescribed pattern is obtained.

The dry etching can be performed using, for example, a publicly known dry etching apparatus. The etching gas used for dry etching can be appropriately selected according to the elemental composition of the film to be etched, and for example, fluorine-based gases such as CHF₃, CF₄, C₂F₆, C₃F₃, and SF₆, chlorine-based gases such as Cl₂ and BCl₃, oxygen-based gases such as O₂, O₃, and H₂O, reducing gases such as H₂, NH₃, CO, CO₂, CH₄, C₂H₂, C₂H₄, C₂H₆, C₃H₄, C₃H₆, C₃H₈, HF, HI, HBr, HCl, NO, and BCl₃, and inert gases such as He, N₂ and Ar are used. These gases can also be mixed and used. When the substrate is etched using the pattern of the resist underlayer film as a mask, a fluorine-based gas is usually used.

### <<Composition for Forming a Resist Underlayer Film>>

The composition for forming a resist underlayer film contains the polymer [A] and the solvent [C]. As such a composition for forming a resist underlayer film, the composition for forming a resist underlayer film to be used in the above-described method for manufacturing a semiconductor substrate can be suitably employed.

### EXAMPLES

Hereinbelow, the present invention will specifically be described on the basis of examples, but is not limited to these examples.

### [Weight-Average Molecular Weight (Mw)]

The Mw of a polymer (x-1) was measured by gel permeation chromatography (detector: differential refractometer) with monodisperse polystyrene standards using GPC columns (“G2000HXL”×2 and “G3000HXL”×1) manufactured by Tosoh Corporation under the following analysis conditions: flow rate: 1.0 mL/min; elution solvent: tetrahydrofuran; column temperature: 40° C.

### [Average Thickness of Film]

The average thickness of a film was determined as a value obtained by measuring the film thickness at arbitrary nine points at intervals of 5 cm including the center of the resist underlayer film formed on a silicon wafer, using a spectroscopic ellipsometer (“M2000D” available from J. A. WOOLLAM Co.) and calculating the average value of the film thicknesses.

### <Synthesis and Procurement of Monomers>

### [Synthesis of Neopentyl Styrenesulfonate]

A 2 L three-necked flask equipped with a Dimroth condenser, a dropping funnel, and a stirrer bar was charged with 166 mL of dimethylformamide, 50 g of sodium styrenesulfonate, and 0.5 g of di-tert-butylcatechol, and then 87 mL of thionyl chloride was slowly dropped from the dropping funnel under ice cooling, and the resulting mixture was stirred for 3 hours. After the stirring, ice was added little by little in an amount of about 50 g to decompose an excess amount of thionyl chloride. Thereafter, 100 g of diisopropyl ether was added, and extraction was performed twice. The diisopropyl ether layer was dried over sodium sulfate, and the sodium sulfate was removed by filtration with a pleated filter paper. The diisopropyl ether solution was concentrated under reduced pressure, the yield was then determined by weighing, 131.9 g of pyridine and 70 g of neopentyl alcohol were added, and the resulting mixture was stirred for 3 hours under ice cooling. This reaction solution was washed three times with a 1 N aqueous HCl solution, and further washed with methylene chloride and water to remove pyridine and pyridine hydrochloride. The methylene chloride layer was dried over sodium sulfate, and then methylene chloride was distilled off under reduced pressure. The golden liquid was purified by silica gel column chromatography with methylene chloride/n-hexane=2/1, affording a transparent liquid (yield: 67%). The structure of the target product was identified by 1H-NMR and GC-MS spectra.

¹H-NMR (CDCl₃); 7.87 (d, 2H, Ph), 7.54 (d, 2H, Ph), 6.75 (q, 1H, CH), 5.93 (d, 1H, CH₂), 5.48 (d, 1H, CH₂), 3.67 (s, 2H, CH₂), 0.91 (s, 9H, CH₃).

GC-MASS (M/Z); 254

### [Ethyl Styrenesulfonate]

Ethyl styrenesulfonate was obtained from Tosoh Finechem Corporation.

### Synthesis of 3-phenyl-3,4-dihydro-2H-1,3-benzoxazine-6-carboxaldehyde

A 300 mL three-necked flask equipped with a dropping funnel and a Dimroth condenser was charged with 3 g of paraformaldehyde and 30 mL of toluene, then 4.66 g of aniline and 10 g of toluene were added dropwise from the dropping funnel, and the resulting mixture was stirred for 30 minutes under ice cooling. Next, 6.1 g of 4-hydroxybenzaldehyde was charged in a solid form along a filter paper into the three-necked flask through the center of the flask, and the resulting mixture was heated and melted at 95° C. for 5 hours in a nitrogen atmosphere, and stirred until the system became homogeneous. After completion of the reaction, the reaction solution was concentrated, 60 mL of methylene chloride was added, 50 mL of a 2.5% aqueous sodium hydroxide solution was added, and a washing operation was repeated three times. The organic layer was collected and concentrated, then the eggplant flask was immersed in dry ice acetone to precipitate crystals, 20 mL of toluene was added to dissolve the crystals, and then purification was conducted by recrystallization. The obtained crystals were collected by filtration with a Buchner funnel, affording 6.4 g of a white solid. The structure of the target product was confirmed by ¹H-NMR.

¹H-NMR (CDCl₃); 9.79 (1H, s, CHO), 7.60 (1H, m, Ph), 7.54 (1H, m, Ph), 7.25 (1H, m, Ph), 7.09 (2H, m, Ph), 6.94 (1H, m, Ph), 6.89 (1H, m, Ph), 5.41 (2H, m, CH₂), 4.64 (2H, m, CH₂).

### Synthesis of 6-ethenyl-3-phenyl-3,4-dihydro-2H-1,3-benzoxazine

A 500 mL three-necked flask equipped with a Dimroth condenser and a dropping funnel was charged with 12.5 g (35 mmol) of methyltriphenylphosphine bromide and 3.93 g (35 mmol) of potassium t-butoxide, affording a vivid yellow slurry ylide reagent. Next, 6 g (25 mmol) of 3-phenyl-3,4-dihydro-2H-1,3-benzoxazine-6-carboxaldehyde and 50 mL of dry THF were added dropwise to precipitate phosphine oxide, and a Wittig reaction was allowed to proceed. The residue was extracted twice with chloroform, and the chloroform layer was washed four times with water. The organic layer was concentrated and purified by column chromatography (n-hexane/ethyl acetate=6/1). The structure of the target product was confirmed by ¹H-NMR.

¹H-NMR (CDCl₃); 7.60 (1H, m, Ph), 7.28 (1H, m, Ph), 7.21 (2H, m, Ph), 6.94 (2H, m, Ph), 6.89 (1H, m, Ph), 6.80 (1H, m, Ph), 6.72 (1H, m, CH₂═CH—), 5.76 (1H, m, CH₂═CH—), 5.41 (2H, m, CH₂), 5.25 (1H, m, CH₂═CH—), 4.64 (2H, m, CH₂).

### Synthesis of 4-nonafluorobutylstyrene

A 500 mL three-necked flask equipped with a dropping funnel and a Dimroth condenser was charged with 20.1 g of 4-chlorostyrene, 3.65 g of magnesium, and 200 mL of dry THF, and the resulting mixture was heated and refluxed for 2 hours. After cooling to about 50° C., 51.9 g of 4-iodononafluorobutane was added, and a Grignard reaction was performed at 50° C. for about 1 hour. After completion of the reaction, a 1 N aqueous sulfuric acid solution was added to precipitate and sediment a Mg salt. The filtrate was collected and concentrated, and then purified by column chromatography with ethyl acetate/hexane=1/1 vol %, affording 28 g of a target product. The structure of the target product was confirmed by ^{T}H-NMR and GC-MASS.

¹H-NMR (CDCl₃); 7.67 (2H, d, Ph), 7.28 (2H, d, Ph), 6.72 (1H, q, CH), 5.76 (1H, d, CH₂), 5.25 (1H, d, CH₂).

GC-MASS (m/z) 336.

### Synthesis of 5-methyl-2-heptyl styrenesulfonoate

A 300 mL three-necked flask equippedwith a Dimroth condenser, a dropping funnel, and a stirrer bar was charged with 100 mL of dimethylformamide, 30 g of sodium styrenesulfonate, and 0.3 g of di-tert-butylcatechol, and then 75 mL of thionyl chloride was slowly dropped from the dropping funnel under ice cooling, and the resulting mixture was stirred for 3 hours. After the stirring, ice was added little by little in an amount of about 50 g to decompose an excess amount of thionyl chloride. Thereafter, 100 g of diisopropyl ether was added, and extraction was performed twice. The diisopropyl ether layer was dried over sodium sulfate, and the sodium sulfate was removedby filtration with a pleated filter paper. The diisopropyl ether solution was concentrated under reduced pressure, the yield was then determined by weighing, 50.9 g of pyridine and 11.5 g of 5-methyl-2-heptanol were added, and the resulting mixture was stirred for 5 hours under ice cooling. This reaction solution was washed three times with a 1 N aqueous HCl solution, and further washed with methylene chloride and water to remove pyridine and pyridine hydrochloride. The methylene chloride layer was dried over sodium sulfate, and then methylene chloride was distilled off under reduced pressure. The golden liquid was purified by silica gel column chromatography with methylene chloride/n-hexane=1/1, affording a transparent liquid (yield: 56%). The structure of the target product was identified by ¹H-NMR and GC-MS spectra.

¹H-NMR (400 MHz, CDCl₃) 5; 7.75 (m, 2H, m-Ph), 7.68 (m, 2H, o-Ph), 6.72 (q, 1H, CH₂═CH—), 5.76 (d, 1H, CH₂═CH—), 5.25 (d, 1H, CH₂═CH—), 4.80 (m, 1H, SOOOCH—), 1.62 (m, 1H, —CH—), 1.40-1.39 (m, 5H, CH₂, CH₃), 1.19 (m, 2H, —CH₂—), 0.9 (d, 6H, CH₃).

GC-MASS; m/z 282

### Synthesis of vinylbenzyl methanesulfonate

A 300 mL three-necked flask equipped with a Dimroth condenser, a dropping funnel, and a stirrer bar was charged with 100 mL of methylene chloride and 8.05 g of vinylbenzyl alcohol, and then 8.71 g of methanesulfonic anhydride and 9.50 g of pyridine were slowly dropped from the dropping funnel under ice cooling, and the resulting mixture was stirred for 3 hours. Thereafter, pyridine hydrochloride was removed, 100 g of methylene chloride and 200 g of ultrapure water were added, and washing with water was performed four times. The methylene chloride layer was dried over sodium sulfate, the sodium sulfate was removed by filtration with a pleated filter paper, and methylene chloride was distilled off under reduced pressure. The golden liquid was purified by silica gel column chromatography with methylene chloride/n-hexane=1/9, affording a transparent liquid (yield: 73%). The structure of the target product was identified by ^{T}H-NMR and GC-MS spectra.

¹H-NMR (400 MHz, CDCl₃) 5; 7.67 (m, 2H, m-Ph), 7.23 (m, 2H, o-Ph), 6.72 (q, 1H, CH₂═CH—), 5.76 (d, 1H, CH₂═CH—), 5.25 (d, 1H, CH₂═CH—), 4.79 (m, 2H, vPhCH₂—), 3.16 (s, 3H, —CH₃).

GC-MASS; m/z 212

### Synthesis of vinylbenzyl p-toluenesulfonate

A 300 mL three-necked flask equipped with a Dimroth condenser, a dropping funnel, and a stirrer bar was charged with 100 mL of methylene chloride and 8.05 g of vinylbenzyl alcohol, and then 9.53 g of p-toluenesulfonic acid chloride and 9.50 g of pyridine were slowly dropped from the dropping funnel under ice cooling, and the resulting mixture was stirred for 3 hours. Thereafter, pyridine hydrochloride was removed, 100 g of methylene chloride and 200 g of ultrapure water were added, and washing with water was performed four times. The methylene chloride layer was dried over sodium sulfate, the sodium sulfate was removed by filtration with a pleated filter paper, and methylene chloride was distilled off under reduced pressure. The golden liquid was purified by silica gel column chromatography with methylene chloride/n-hexane=1/9, affording a transparent liquid (yield: 73%). The structure of the target product was identified by ^{T}H-NMR and GC-MS spectra.

¹H-NMR (400 MHz, CDCl₃) 5; 7.75 (m, 2H, m-Ph) 7.67 (m, 2H, m-Ph), 7.45 (m, 2H, m-Ph), 7.23 (m, 2H, o-Ph), 6.72 (q, 1H, CH₂═CH—), 5.76 (d, 1H, CH₂═CH—), 5.25 (d, 1H, CH₂═CH—), 4.79 (m, 2H, vPhCH₂—), 2.43 (s, 3H, —CH₃).

GC-MASS; m/z 289

### Synthesis of vinylbenzyl trifluoromethanesulfonate

A 300 mL three-necked flask equipped with a Dimroth condenser, a dropping funnel, and a stirrer bar was charged with 100 mL of methylene chloride and 8.05 g of vinylbenzyl alcohol, and then 8.42 g of trifluoromethanesulfonic acid chloride and 9.50 g of pyridine were slowly dropped from the dropping funnel under ice cooling, and the resulting mixture was stirred for 3 hours. Thereafter, pyridine hydrochloride was removed, 100 g of methylene chloride and 200 g of ultrapure water were added, and washing with water was performed four times. The methylene chloride layer was dried over sodium sulfate, the sodium sulfate was removed by filtration with a pleated filter paper, and methylene chloride was distilled off under reduced pressure. The golden liquid was purified by silica gel column chromatography with methylene chloride/n-hexane=1/9, affording a transparent liquid (yield: 68%). The structure of the target product was identified by 1H-NMR and GC-MS spectra.

¹H-NMR (400 MHz, CDCl₃) 5; 7.67 (m, 2H, m-Ph), 7.23 (m, 2H, o-Ph), 6.72 (q, 1H, CH₂═CH—), 5.76 (d, 1H, CH₂═CH—), 5.25 (d, 1H, CH₂═CH—), 4.79 (m, 2H, vPhCH₂—)

GC-MASS; m/z 266

### Synthesis of polymer [A]

The polymer [A] was synthesized by the following procedure. In the formulas shown in the Synthesis Examples disclosed below, the number attached to each repeating unit represents the content ratio (mol %) of the repeating unit. When no number is attached to a repeating unit, the content ratio of the repeating unit is 100 mol %. The composition ratio was confirmed by ¹³C-NMR.

### [Synthesis Example 1-1] (Synthesis of Polymer (A-1))

Into a three-necked flask equipped with a thermometer, a Dimroth condenser, and a stirrer bar was charged 10 g of dimethylformamide, which was then kept at 80° C. A mixed liquid of 7.63 g of neopentyl styrenesulfonate, 1.39 g of dimethyl 2,2-azobis(2-methylpropionate), and 20.4 g of dimethylformamide was added dropwise from a feeder over 3 hours. After completion of the dropwise addition, the mixture was aged at 80° C. for 3 hours. The obtained polymerization liquid was precipitated and purified with 10 times amount of methanol, affording 7.50 g (yield: 98%) of polymer (A-1) represented by formula as a white solid. The obtained polymer (A-1) had an Mw of 4440, an Mn of 2670, and a PDI (molecular weight dispersion) of 1.66.

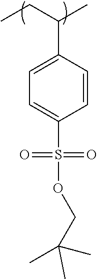

### [Synthesis Example 1-2] (Synthesis of Polymer (A-2))

Into a three-necked flask equipped with a thermometer, a Dimroth condenser, and a stirrer bar was charged 10 g of dimethylformamide, which was then kept at 80° C. A mixed liquid of 6.36 g of ethyl styrenesulfonate, 1.38 g of dimethyl 2,2-azobis(2-methylpropionate), and 20.4 g of dimethylformamide was added dropwise from a feeder over 3 hours. After completion of the dropwise addition, the mixture was aged at 80° C. for 3 hours. The obtained polymerization liquid was precipitated and purified with 10 times amount of methanol, affording 6.20 g (yield: 97%) of polymer (A-2) represented by formula as a white solid. The obtained polymer (A-2) had an Mw of 4250, an Mn of 2390, and a PDI of 1.77.

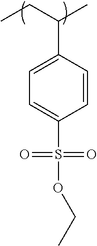

### [Synthesis Example 1-3] (Synthesis of Polymer (A-3))

Into a three-necked flask equipped with a thermometer, a Dimroth condenser, and a stirrer bar was charged 10 g of dimethylformamide, which was then kept at 80° C. A mixed liquid of 8.46 g of 5-methyl-2-heptyl styrenesulfonate, 1.38 g of dimethyl 2,2-azobis(2-methylpropionate), and 20.0 g of dimethylformamide was added dropwise from a feeder over 3 hours. After completion of the dropwise addition, the mixture was aged at 80° C. for 3 hours. The obtained polymerization liquid was precipitated and purified with 10 times amount of methanol, affording 8 g (yield: 95%) of polymer (A-3) represented by formula as a white solid. The obtained polymer (A-3) had an Mw of 4520, an Mn of 2430, and a PDI of 1.86.

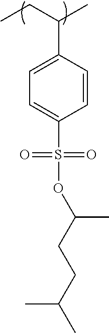

### [Synthesis Example 1-4] (Synthesis of Polymer (A-4))

Into a three-necked flask equipped with a thermometer, a Dimroth condenser, and a stirrer bar was charged 10 g of dimethylformamide, which was then kept at 80° C. A mixed liquid of 4.34 g of neopentyl styrenesulfonate, 2.66 g of styrene, 1.96 g of dimethyl 2,2-azobis(2-methylpropionate), and 20.0 g of dimethylformamide was added dropwise from a feeder over 3 hours. After completion of the dropwise addition, the mixture was aged at 80° C. for 3 hours. The obtained polymerization liquid was precipitated and purified with 10 times amount of methanol, affording 2.5 g (yield: 36%) of polymer (A-4) represented by formula as a white solid. The obtained polymer (A-4) had an Mw of 3680, an Mn of 1980, and a PDI of 1.86.

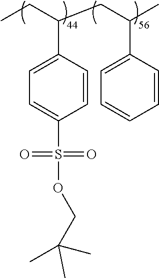

### [Synthesis Example 1-5] (Synthesis of Polymer (A-5))

Into a three-necked flask equipped with a thermometer, a Dimroth condenser, and a stirrer bar was charged 10 g of dimethylformamide, which was then kept at 80° C. A mixed liquid of 3.45 g of neopentyl styrenesulfonate, 3.57 g of tert-butoxystyrene, 1.55 g of dimethyl 2,2-azobis(2-methylpropionate), and 20.0 g of dimethylformamide was added dropwise from a feeder over 3 hours. After completion of the dropwise addition, the mixture was aged at 80° C. for 3 hours. The obtained polymerization liquid was precipitated and purified with 10 times amount of methanol, affording 6.50 g (yield: 93%) of polymer (A-5) represented by formula as a white solid. The obtained polymer (A-5) had an Mw of 4120, an Mn of 2180, and a PDI of 1.89.

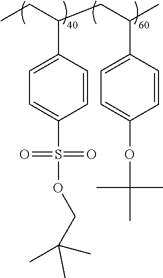

### [Synthesis Example 1-6] (Synthesis of Polymer (A-6))

Into a three-necked flask equipped with a thermometer, a Dimroth condenser, and a stirrer bar was charged 10 g of dimethylformamide, which was then kept at 80° C. A mixed liquid of 2.92 g of neopentyl styrenesulfonate, 4.08 g of 6-ethenyl-3-phenyl-3,4-dihydro-2H-1,3-benzoxazine, 1.32 g of dimethyl 2,2-azobis(2-methylpropionate), and 20.0 g of dimethylformamide was added dropwise from a feeder over 3 hours. After completion of the dropwise addition, the mixture was aged at 80° C. for 3 hours. The obtained polymerization liquid was precipitated and purified with 10 times amount of methanol, affording 6.0 g (yield: 86%) of polymer (A-6) represented by formula as a white solid. The obtained polymer (A-6) had an Mw of 4020, an Mn of 2670, and a PDI of 1.51.

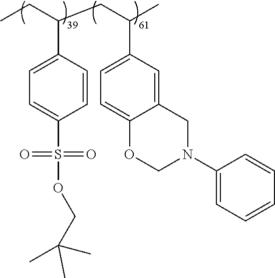

### [Synthesis Example 1-7] (Synthesis of Polymer (A-7))

Into a three-necked flask equipped with a thermometer, a Dimroth condenser, and a stirrer bar was charged 10 g of dimethylformamide, which was then kept at 80° C. A mixed liquid of 4.45 g of neopentyl styrenesulfonate, 2.55 g of isopropenyloxazoline, 2.02 g of dimethyl 2,2-azobis(2-methylpropionate), and 20.0 g of dimethylformamide was added dropwise from a feeder over 3 hours. After completion of the dropwise addition, the mixture was aged at 80° C. for 3 hours. The obtained polymerization liquid was precipitated and purified with 10 times amount of methanol, affording 4.3 g (yield: 61%) of polymer (A-7) represented by formula as a white solid. The obtained polymer (A-7) had an Mw of 4170, an Mn of 2270, and a PDI of 1.84.

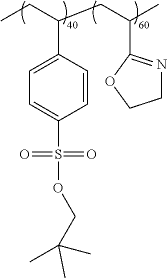

### [Synthesis Example 1-8] (Synthesis of Polymer (A-8))

Into a three-necked flask equipped with a thermometer, a Dimroth condenser, and a stirrer bar was charged 10 g of dimethylformamide, which was then kept at 80° C. A mixed liquid of 3.43 g of neopentyl styrenesulfonate, 3.57 g of glycidyl 4-vinylphenyl ether, 1.55 g of dimethyl 2,2-azobis(2-methylpropionate), and 20.0 g of dimethylformamide was added dropwise from a feeder over 3 hours. After completion of the dropwise addition, the mixture was aged at 80° C. for 3 hours. The obtained polymerization liquid was precipitated and purified with 10 times amount of methanol, affording 6.60 g (yield: 94%) of polymer (A-8) represented by formula as a white solid. The obtained polymer (A-8) had an Mw of 4320, an Mn of 2720, and a PDI of 1.59.

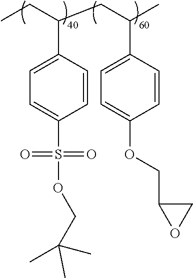

### [Synthesis Example 1-9] (Synthesis of Polymer (A-9))

Into a three-necked flask equipped with a thermometer, a Dimroth condenser, and a stirrer bar was charged 10 g of dimethylformamide, which was then kept at 80° C. A mixed liquid of 3.74 g of neopentyl styrenesulfonate, 3.26 g of 4-vinylbenzyl methyl ether, 1.69 g of dimethyl 2,2-azobis(2-methylpropionate), and 20.0 g of dimethylformamide was added dropwise from a feeder over 3 hours. After completion of the dropwise addition, the mixture was aged at 80° C. for 3 hours. The obtained polymerization liquid was precipitated and purified with 10 times amount of methanol, affording 6.90 g (yield: 99%) of polymer (A-9) represented by formula as a white solid. The obtained polymer (A-9) had an Mw of 4720, an Mn of 2890, and a PDI of 1.63.

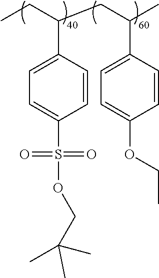

### [Synthesis Example 1-10] (Synthesis of Polymer (A-10))

Into a three-necked flask equipped with a thermometer, a Dimroth condenser, and a stirrer bar was charged 10 g of dimethylformamide, which was then kept at 80° C. A mixed liquid of 2.41 g of neopentyl styrenesulfonate, 4.59 g of 4-nonafluorobutylstyrene, 1.09 g of dimethyl 2,2-azobis(2-methylpropionate), and 20.0 g of dimethylformamide was added dropwise from a feeder over 3 hours. After completion of the dropwise addition, the mixture was aged at 80° C. for 3 hours. The obtained polymerization liquid was precipitated and purified with 10 times amount of methanol, affording 4.8 g (yield: 67%) of polymer (A-10) represented by formula as a white solid. The obtained polymer (A-10) had an Mw of 4570, an Mn of 2890, and a PDI of 1.58.

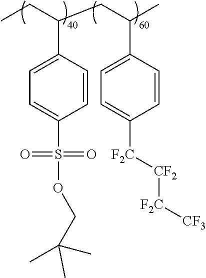

### [Synthesis Example 1-11] (Synthesis of Polymer (A-11))

Into a three-necked flask equipped with a thermometer, a Dimroth condenser, and a stirrer bar was charged 10 g of dimethylformamide, which was then kept at 80° C. A mixed liquid of 2.84 g of neopentyl styrenesulfonate, 2.69 g of 4-nonafluorobutylstyrene, 1.47 g of tert-butoxystyrene, 1.28 g of dimethyl 2,2-azobis(2-methylpropionate), and 20.0 g of dimethylformamide was added dropwise from a feeder over 3 hours. After completion of the dropwise addition, the mixture was aged at 80° C. for 3 hours. The obtained polymerization liquid was precipitated and purified with 10 times amount of methanol, affording 5.5 g (yield: 79%) of polymer (A-11) represented by formula as a white solid. The obtained polymer (A-11) had an Mw of 3890, an Mn of 2090, and a PDI of 1.86.

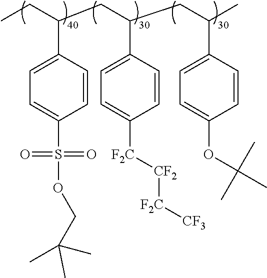

### [Synthesis Example 1-12] (Synthesis of Polymer (A-12))

Into a three-necked flask equipped with a thermometer, a Dimroth condenser, and a stirrer bar was charged 10 g of dimethylformamide, which was then kept at 80° C. A mixed liquid of 4.22 g of nonafluorobutyl styrenesulfonate, 2.78 g of tert-butoxystyrene, 1.21 g of dimethyl 2,2-azobis(2-methylpropionate), and 20.0 g of dimethylformamide was added dropwise from a feeder over 3 hours. After completion of the dropwise addition, the mixture was aged at 80° C. for 3 hours. The obtained polymerization liquid was precipitated and purified with 10 times amount of methanol, affording 3.80 g (yield: 54%) of polymer (A-12) represented by formula as a white solid. The obtained polymer (A-12) had an Mw of 4010, an Mn of 2240, and a PDI of 1.79.

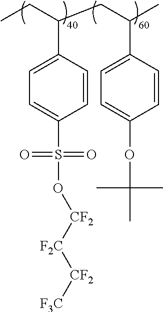

### [Synthesis Example 1-13] (Synthesis of Polymer (A-13))

Into a three-necked flask equipped with a thermometer, a Dimroth condenser, and a stirrer bar was charged 10 g of dimethylformamide, which was then kept at 80° C. A mixed liquid of 7.00 g of 4-vinylbenzyl methanesulfonate, 1.52 g of dimethyl 2,2-azobis(2-methylpropionate), and 20.0 g of dimethylformamide was added dropwise from a feeder over 3 hours. After completion of the dropwise addition, the mixture was aged at 80° C. for 3 hours. The obtained polymerization liquid was precipitated and purified with 10 times amount of methanol, affording 6.8 g (yield: 97%) of polymer (A-13) represented by formula as a white solid. The obtained polymer (A-13) had an Mw of 4240, an Mn of 2570, and a PDI of 1.65.

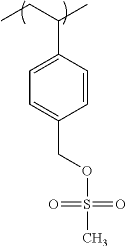

### [Synthesis Example 1-14] (Synthesis of Polymer (A-14))

Into a three-necked flask equipped with a thermometer, a Dimroth condenser, and a stirrer bar was charged 10 g of dimethylformamide, which was then kept at 80° C. A mixed liquid of 7.00 g of 4-vinylbenzyl p-toluenesulfonate, 1.12 g of dimethyl 2,2-azobis(2-methylpropionate), and 20.0 g of dimethylformamide was added dropwise from a feeder over 3 hours. After completion of the dropwise addition, the mixture was aged at 80° C. for 3 hours. The obtained polymerization liquid was precipitated and purified with 10 times amount of methanol, affording 6.9 g (yield: 99%) of polymer (A-14) represented by formula as a white solid. The obtained polymer (A-14) had an Mw of 4340, an Mn of 2580, and a PDI of 1.68.

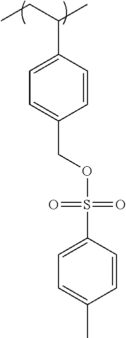

### [Synthesis Example 1-15] (Synthesis of Polymer (A-15))

Into a three-necked flask equipped with a thermometer, a Dimroth condenser, and a stirrer bar was charged 10 g of dimethylformamide, which was then kept at 80° C. A mixed liquid of 7.00 g of 4-vinylbenzyl trifluoromethanesulfonate, 1.21 g of dimethyl 2,2-azobis(2-methylpropionate), and 20.0 g of dimethylformamide was added dropwise from a feeder over 3 hours. After completion of the dropwise addition, the mixture was aged at 80° C. for 3 hours. The obtained polymerization liquid was precipitated and purified with 10 times amount of methanol, affording 6.9 g (yield: 99%) of polymer (A-15) represented by formula as a white solid. The obtained polymer (A-15) had an Mw of 4530, an Mn of 2680, and a PDI of 1.69.

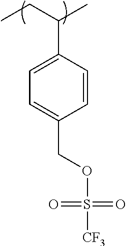

### [Synthesis Example 1-16] (Synthesis of Polymer (A-16))

Into a three-necked flask equipped with a thermometer, a Dimroth condenser, and a stirrer bar was charged 10 g of dimethylformamide, which was then kept at 80° C. A mixed liquid of 3.51 g of 4-vinylbenzyl trifluoromethanesulfonate, 3.49 g of 4-tert-butylstyrene, 1.52 g of dimethyl 2,2-azobis(2-methylpropionate), and 20.0 g of dimethylformamide was added dropwise from a feeder over 3 hours. After completion of the dropwise addition, the mixture was aged at 80° C. for 3 hours. The obtained polymerization liquid was precipitated and purified with 10 times amount of methanol, affording 6.3 g (yield: 90%) of polymer (A-16) represented by formula as a white solid. The obtained polymer (A-16) had an Mw of 4320, an Mn of 2420, and a PDI of 1.79.

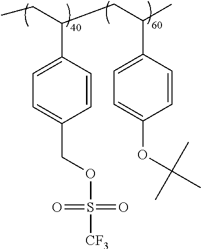

### [Synthesis Example 1-17] (Synthesis of Polymer (A-17))

Into a three-necked flask equipped with a thermometer, a Dimroth condenser, and a stirrer bar was charged 10 g of dimethylformamide, which was then kept at 80° C. A mixed liquid of 3.66 g of 4-vinylbenzyl p-toluenesulfonate, 3.34 g of 4-tert-butylstyrene, 1.46 g of dimethyl 2,2-azobis(2-methylpropionate), and 20.0 g of dimethylformamide was added dropwise from a feeder over 3 hours. After completion of the dropwise addition, the mixture was aged at 80° C. for 3 hours. The obtained polymerization liquid was precipitated and purified with 10 times amount of methanol, affording 6.4 g (yield: 92%) of polymer (A-17) represented by formula as a white solid. The obtained polymer (A-17) had an Mw of 4670, an Mn of 2520, and a PDI of 1.85.

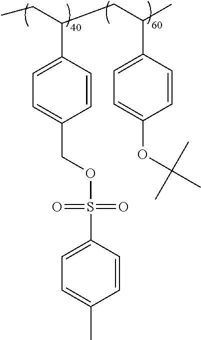

### [Synthesis Example 1-18] (Synthesis of Polymer (A-18))

Into a three-necked flask equipped with a thermometer, a Dimroth condenser, and a stirrer bar was charged 6 g of methyl isobutyl ketone, which was then kept at 80° C. A mixed liquid of 2.75 g of neopentyl 4-acryloyloxybenzenesulfonate, 1.60 g of N-phenylmaleimide, 1.65 g of vinylbenzyl alcohol, 1.42 g of dimethyl 2,2-azobis(2-methylpropionate), and 12 g of methyl isobutyl ketone was added dropwise over 3 hours. After completion of the dropwise addition, the mixture was aged at 80° C. for 3 hours. The obtained polymerization liquid was precipitated and purified in 10 times amount of methanol, affording polymer (A-18) represented by formula as a white solid. The obtained polymer (A-18) had an Mw of 7400, an Mn of 4370, and a PDI of 1.69.

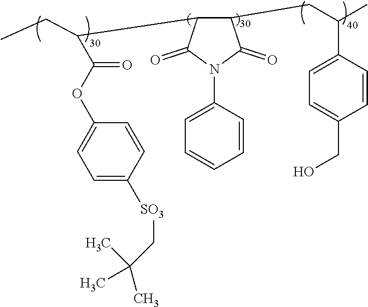

### [Synthesis Example 1-19] (Synthesis of Polymer (A-19))

Into a three-necked flask equipped with a thermometer, a Dimroth condenser, and a stirrer bar was charged 6 g of methyl isobutyl ketone, which was then kept at 0° C. A mixed liquid of 3.06 g of neopentyl 4-acryloyloxy-2-trifluoromethylbenzenesulfonate, 1.45 g of N-phenylmaleimide, 1.49 g of vinylbenzyl alcohol, 1.28 g of dimethyl 2,2-azobis(2-methylpropionate), and 12 g of methyl isobutyl ketone was added dropwise over 3 hours. After completion of the dropwise addition, the mixture was aged at 80° C. for 3 hours. The obtained polymerization liquid was precipitated and purified in 10 times amount of methanol, affording polymer (A-19) represented by formula as a white solid. The obtained polymer (A-19) had an Mw of 7860, an Mn of 4530, and a PDI of 1.74.

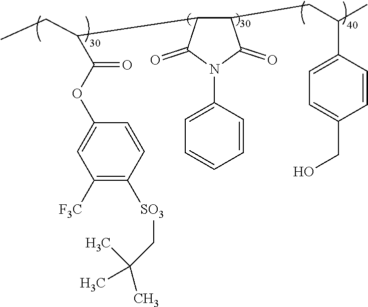

### [Synthesis Example 1-20] (Synthesis of Polymer (A-20))

Into a three-necked flask equipped with a thermometer, a Dimroth condenser, and a stirrer bar was charged 6 g of methyl isobutyl ketone, which was then kept at 0° C. A mixed liquid of 3.31 g of neopentyl 4-acryloyloxy-2,6-bis(trifluoromethyl)benzenesulfonate, 1.32 g of N-phenylmaleimide, 1.37 g of vinylbenzyl alcohol, 1.17 g of dimethyl 2,2-azobis(2-methylpropionate), and 12 g of methyl isobutyl ketone was added dropwise over 3 hours. After completion of the dropwise addition, the mixture was aged at 80° C. for 3 hours. The obtained polymerization liquid was precipitated and purified in 10 times amount of methanol, affording polymer (A-20) represented by formula as a white solid. The obtained polymer (A-20) had an Mw of 8090, an Mn of 4980, and a PDI of 1.62.

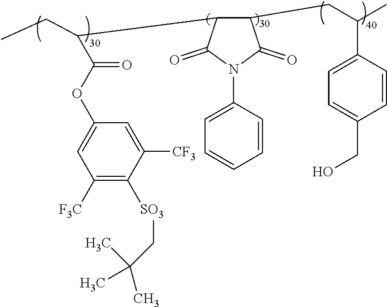

### [Synthesis Example 1-21] (Synthesis of Polymer (A-21))

Into a three-necked flask equipped with a thermometer, a Dimroth condenser, and a stirrer bar was charged 6 g of methyl isobutyl ketone, which was then kept at 0° C. A mixed liquid of 2.39 g of neopentyl styrenesulfonate, 1.63 g of N-phenylmaleimide, 1.98 g of 4-propargyloxystyrene, 1.44 g of dimethyl 2,2-azobis(2-methylpropionate), and 12 g of methyl isobutyl ketone was added dropwise over 3 hours. After completion of the dropwise addition, the mixture was aged at 80° C. for 3 hours. The obtained polymerization liquid was precipitated and purified in 10 times amount of methanol, affording polymer (A-21) represented by formula as a white solid. The obtained polymer (A-21) had an Mw of 7820, an Mn of 4820, and a PDI of 1.62.

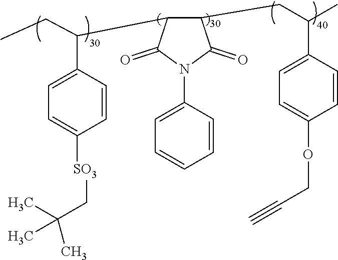

### [Synthesis Example 1-22] (Synthesis of Polymer (A-22))

Into a three-necked flask equipped with a thermometer, a Dimroth condenser, and a stirrer bar was charged 6 g of methyl isobutyl ketone, which was then kept at 0° C. A mixed liquid of 2.62 g of neopentyl acrylic acid-benzenesulfonate, 1.52 g of N-phenylmaleimide, 1.85 g of 4-propargyloxystyrene, 1.35 g of dimethyl 2,2-azobis(2-methylpropionate), and 12 g of methyl isobutyl ketone was added dropwise over 3 hours. After completion of the dropwise addition, the mixture was aged at 80° C. for 3 hours. The obtained polymerization liquid was precipitated and purified in 10 times amount of methanol, affording polymer (A-22) represented by formula as a white solid. The obtained polymer (A-22) had an Mw of 7750, an Mn of 4860, and a PDI of 1.59.

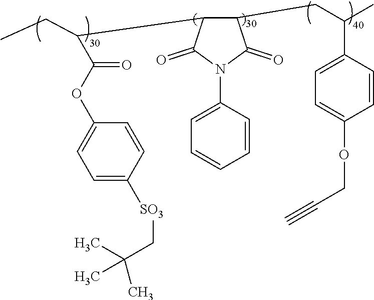

### Synthesis of Polymer [B]

The polymers represented by formulas (B-1) to (B-3) (hereinafter also referred to as “polymers (B-1)” and the like) were each synthesized by the following procedure.

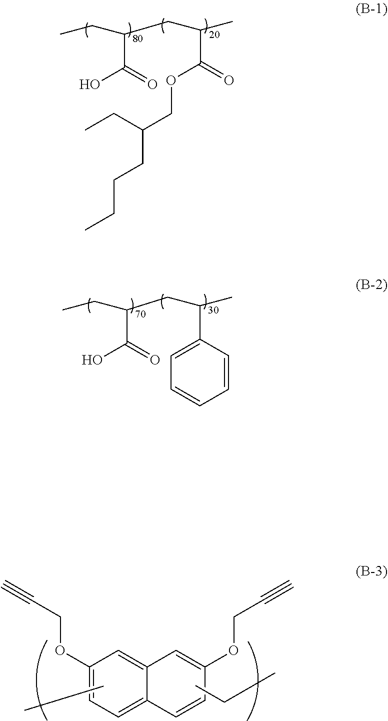

### [Synthesis Example 2-1] (Synthesis of Polymer (B-1))

63 g of acrylic acid, 36 g of 2-ethylhexyl acrylate, and 21.2 g of dimethyl 2,2′-azobis(2-methylpropionate) were added to prepare a monomer solution. In a nitrogen atmosphere, 300 g of methyl isobutyl ketone was placed in a reaction vessel and heated to 80° C., and the monomer solution was added dropwise over 3 hours with stirring. A polymerization reaction was performed for 6 hours with the start of the dropwise addition regarded as the start time of the polymerization reaction, and then the resulting mixture was cooled to 30° C. or lower. To the resulting reaction solution was added 300 g of propylene glycol monomethyl ether, and methyl isobutyl ketone was removed by concentration under reduced pressure, affording a propylene glycol monomethyl ether solution of polymer (B-1). The Mw of the polymer (B-1) was 6,500.

### [Synthesis Example 2-2] (Synthesis of Polymer (B-2))

66 g of acrylic acid, 34 g of styrene, and 25.1 g of dimethyl 2,2′-azobis(2-methylpropionate) were added to prepare a monomer solution. In a nitrogen atmosphere, 300 gof methyl isobutyl ketone was placed in a reaction vessel and heated to 80° C., and the monomer solution was added dropwise over 3 hours with stirring. A polymerization reaction was performed for 6 hours with the start of the dropwise addition regarded as the start time of the polymerization reaction, and then the resulting mixture was cooled to 30° C. or lower. To the resulting reaction solution was added 300 g of propylene glycol monomethyl ether, and methyl isobutyl ketone was removed by concentration under reduced pressure, affording a propylene glycol monomethyl ether solution of polymer (B-2). The Mw of the polymer (B-2) was 5,300.

### [Synthesis Example 2-3] Synthesis of Polymer (B-3)

In a nitrogen atmosphere, 29.1 g of 2,7-dihydroxynaphthalene, 14.8 g of a 37% by mass formaldehyde solution, and 87.3 g of methyl isobutyl ketone were charged into a reaction and dissolved. After adding 1.0 g of p-toluenesulfonic acid monohydrate to the reaction vessel, and then the mixture was heated to 85° C. and reacted for 4 hours. After completion of the reaction, the reaction solution was transferred to a separatory funnel, 200 g of methyl isobutyl ketone and 400 g of water were added thereto, and the organic phase was washed. After separating the aqueous phase, the resulting organic phase was concentrated with an evaporator, and the residue was added dropwise to 500 g of methanol, affording a precipitate. The precipitate was collected by suction filtration and washed several times with 100 g of methanol. Then, the washed product was dried at 60° C. for 12 hours using a vacuum dryer, affording polymer (b-3) having a repeating unit represented by formula (b-3). The Mw of the polymer (b-3) was 3,400.

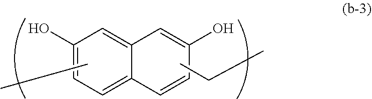

In a nitrogen atmosphere, 16.8 g of the polymer (b-3), 34.9 g of propargyl bromide, 90 g of methyl isobutyl ketone, and 45.0 g of methanol were added to a reaction vessel, and the mixture was stirred. Then, 106.9 g of a 25% by mass aqueous tetramethylammonium hydroxide solution was added thereto, and the mixture was reacted at 50° C. for 6 hours. The reaction solution was cooled to 30° C., and then 200.0 g of a 5% by mass aqueous oxalic acid solution was added. After removing the aqueous phase, the resulting organic phase was concentrated with an evaporator, and the residue was added dropwise to 500 g of methanol, affording a precipitate. The precipitate was collected by suction filtration and washed several times with 100 g of methanol. Then, the washed product was dried at 60° C. for 12 hours using a vacuum dryer, affording polymer (B-3). The Mw of the polymer (B-3) was 3,000.

### Preparation of Composition

The polymer [A], the polymer [B], the solvent [C], the crosslinking agent [D], the acid generating agent [E], and the dehydrating agent [F] used for the preparation of compositions are shown below.

### [Polymer [A]]

Polymers (A-1) to (A-22) synthesized above.

### [Polymer [B]]

Polymers (B-1) to (B-3) synthesized above.

### [Solvent [C]]

C-1: Propylene glycol monomethyl ether acetate
C-2: Propylene glycol monomethyl ether
C-3: 4-Methyl-2-pentanol
C-4: Ethyl lactate
C-5: 2,2-Dimethyl-1-propanol

### [Crosslinking Agent [D]]

D-1: Compound represented by formula (D-1)
D-2: Compound represented by formula (D-2)
D-3: Compound represented by formula (D-3)

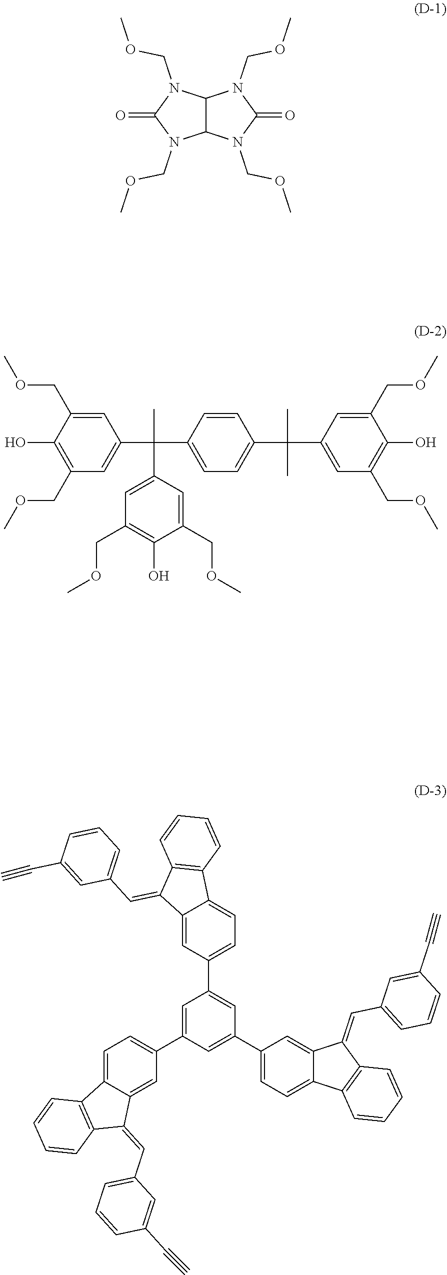

### [Acid Generating Agent [E] ]

E-1: Compound represented by formula (E-1)
E-2: Compound represented by formula (E-2)
E-3: Compound represented by formula (E-3)

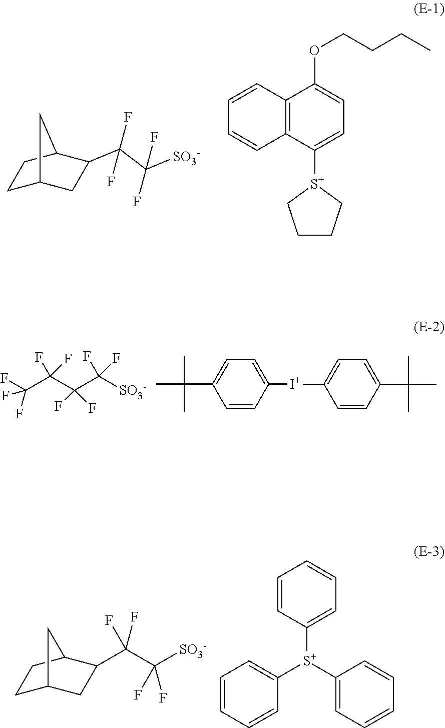

### [Dehydrating Agent [F] ]

F-1: Trimethyl orthoformate

### Example 1

In 1100 parts by mass of (C-1) and 200 parts by mass of (C-2) as the solvent [C] were dissolved 50 parts by mass of (A-1) as the polymer [A] and 50 parts by mass of (D-1) as the crosslinking agent [D]. The resulting solution was filtered through a polytetrafluoroethylene (PTFE) membrane filter having a pore size of 0.45 μm to prepare a composition (J-1).

### Examples 2 to 35 and Comparative Examples 1 to 3

Compositions (J-2) to (J-35) and (CJ-1) to (CJ-3) were prepared in the same manner as in Example 1 except that the components of the types and contents shown in the following Table 1 were used. “-” in the columns [A], [B], [D], [E], and [F] in Table 1 each indicate that the corresponding component was not used.

TABLE 1

| | | | | | | | | Crosslinking | | Acid generating | | Dehydrating | |
|---|---|---|---|---|---|---|---|---|---|---|---|---|---|
| | | Polymer [A] | | Polymer [B] | | Solvent [C] | | agent [D] | | agent [E] | | agent [F] | |
| | | | Content | | Content | | Content | | Content | | Content | | Content |
| | | | (parts by | | (parts by | | (parts by | | (parts by | | (parts by | | (parts by |
| | Composition | Type | mass) | Type | mass) | Type | mass) | Type | mass) | Type | mass) | Type | mass) |
| Example 1 | J-1 | A-1 | 50 | — | — | C-1/C-2 | 1100/200 | D-1 | 50 | — | — | — | — |
| Example 2 | J-2 | A-2 | 50 | — | — | C-1/C-2 | 1100/200 | D-1 | 50 | — | — | — | — |
| Example 3 | J-3 | A-3 | 50 | — | — | C-1/C-2 | 1100/200 | D-1 | 50 | — | — | — | — |
| Example 4 | J-4 | A-4 | 50 | — | — | C-1/C-2 | 1100/200 | D-1 | 50 | E-3 | 10 | — | — |
| Example 5 | J-5 | A-5 | 100 | — | — | C-1/C-3 | 1100/200 | — | — | — | — | — | — |
| Example 6 | J-6 | A-5 | 100 | — | — | C-1/C-4 | 1100/200 | — | — | E-1 | 10 | — | — |
| Example 7 | J-7 | A-6 | 100 | — | — | C-1/C-4 | 1100/200 | — | — | E-2 | 10 | — | — |
| Example 8 | J-8 | A-7 | 100 | — | — | C-1/C-3 | 1100/200 | — | — | — | — | — | — |
| Example 9 | J-9 | A-7 | 100 | — | — | C-1/C-3 | 1100/200 | — | — | E-2 | 10 | — | — |
| Example 10 | J-10 | A-8 | 100 | — | — | C-1/C-3 | 1100/200 | — | — | — | — | — | — |
| Example 11 | J-11 | A-9 | 100 | — | — | C-1/C-3 | 1100/200 | — | — | E-2 | 10 | — | — |
| Example 12 | J-12 | A-10 | 50 | — | — | C-1/C-3 | 1100/200 | D-1 | 50 | — | — | — | — |
| Example 13 | J-13 | A-11 | 100 | — | — | C-1/C-3 | 1100/200 | — | — | — | — | — | — |
| Example 14 | J-14 | A-12 | 100 | — | — | C-1/C-3 | 1100/200 | — | — | — | — | — | — |
| Example 15 | J-15 | A-12 | 100 | — | — | C-1/C-3 | 1100/200 | — | — | E-2 | 10 | — | — |
| Example 16 | J-16 | A-1 | 50 | B-1 | 50 | C-1 | 1300 | — | — | — | — | — | — |
| Example 17 | J-17 | A-1 | 50 | B-2 | 50 | C-1 | 1300 | — | — | — | — | — | — |
| Example 18 | J-18 | A-1 | 40 | B-1 | 60 | C-1 | 1300 | — | — | — | — | — | — |
| Example 19 | J-19 | A-1 | 40 | B-2 | 60 | C-1 | 1300 | — | — | — | — | — | — |
| Example 20 | J-20 | A-1 | 50 | — | — | C-1/C-5 | 1100/200 | D-2 | 50 | E-3 | 10 | F-1 | 1 |
| Example 21 | J-21 | A-5 | 50 | — | — | C-1/C-4 | 1100/200 | D-2 | 50 | E-3 | 10 | — | — |
| Example 22 | J-22 | A-6 | 50 | — | — | C-1/C-3 | 1100/200 | D-2 | 50 | E-2 | 10 | — | — |
| Example 23 | J-23 | A-8 | 50 | — | — | C-1/C-3 | 1100/200 | D-2 | 50 | E-1 | 10 | — | — |
| Example 24 | J-24 | A-13 | 50 | — | — | C-1/C-2 | 1100/200 | D-2 | 50 | — | — | — | — |
| Example 25 | J-25 | A-14 | 50 | — | — | C-1/C-3 | 1100/200 | D-2 | 50 | — | — | — | — |
| Example 26 | J-26 | A-15 | 30 | — | — | C-1/C-2 | 1100/200 | D-2 | 70 | — | — | — | — |
| Example 27 | J-27 | A-16 | 100 | — | — | C-1/C-2 | 1100/200 | — | — | — | — | — | — |
| Example 28 | J-28 | A-17 | 100 | — | — | C-1/C-4 | 1100/200 | — | — | — | — | — | — |
| Example 29 | J-29 | A-18 | 100 | — | — | C-1/C-2 | 1100/200 | D-2 | 50 | — | — | — | — |
| Example 30 | J-30 | A-19 | 100 | — | — | C-1/C-2 | 1100/200 | D-2 | 50 | — | — | — | — |
| Example 31 | J-31 | A-20 | 100 | — | — | C-1/C-2 | 1100/200 | D-2 | 50 | — | — | — | — |
| Example 32 | J-32 | A-21 | 100 | — | — | C-1/C-2 | 1100/200 | D-2 | 50 | — | — | — | — |
| Example 33 | J-33 | A-22 | 100 | — | — | C-1/C-2 | 1100/200 | D-2 | 50 | — | — | — | — |
| Example 34 | J-34 | A-21 | 50 | B-3 | 50 | C-1/C-2 | 1100/200 | — | — | — | — | — | — |
| Example 35 | J-35 | A-22 | 50 | B-3 | 45 | C-1/C-2 | 1100/200 | D-3 | 5 | — | — | — | — |
| Comparative | CJ-1 | — | — | B-1 | 100 | C-2 | 1300 | — | — | E-1 | 10 | — | — |
| Example 1 | | | | | | | | | | | | | |
| Comparative | CJ-2 | — | — | B-2 | 100 | C-2 | 1300 | — | — | E-2 | 10 | — | — |
| Example 2 | | | | | | | | | | | | | |
| Comparative | CJ-3 | — | — | B-1 | 50 | C-1 | 1300 | D-2 | 50 | E-3 | 10 | — | — |
| Example 3 | | | | | | | | | | | | | |

### Evaluation

Using the compositions prepared as described above, the solvent resistance and the resist pattern rectangularity due to EUV exposure were evaluated by the following methods. The evaluation results are shown in Table 2.

### [Solvent Resistance]

A composition prepared above was applied to a 12-inch silicon wafer by spin coating using a spin coater (“CLEAN TRACK ACT 12” available from Tokyo Electron Limited). Next, the resultant was heated at 250° C. for 60 seconds in the air atmosphere, and then cooled at 23° C. for 60 seconds to form a resist underlayer film having an average thickness of 5 nm, thereby affording a substrate with a resist underlayer film, the substrate having a resist underlayer film formed thereon. The obtained substrate with a resist underlayer film was immersed in cyclohexanone (23° C.) for 1 minute. The average film thickness before and after the immersion was measured. Where the average thickness of the resist underlayer film before the immersion was XO and the average thickness of the resist underlayer film after the immersion was X, the absolute value of the numerical value obtained by (X−XO)×100/XO was calculated and taken as the film thickness change rate (%). The solvent resistance was evaluated as “A” (good) when the film thickness change rate was less than 1%, “B” (slightly good) when the film thickness change rate was 1% or more and less than 10%, and “C” (poor) when the film thickness change rate was 10% or more.

### <Preparation of Resist Composition for EUV Exposure (R-1)>

A resist composition (R-1) was obtained by mixing 100 parts by mass of a polymer having a structural unit (1) derived from 4-hydroxystyrene, a structural unit (2) derived from styrene, and a structural unit (3) derived from 4-t-butoxystyrene (content ratio of each structural unit: (1)/(2)/(3)=65/5/30 (mol %)), 1.0 parts by mass of triphenylsulfonium trifluoromethanesulfonate as a radiation-sensitive acid generating agent, and 4,400 parts by mass of ethyl lactate and 1,900 parts by mass of propylene glycol monomethyl ether acetate each as a solvent, and filtering the obtained solution through a filter having a pore size of 0.2 μm.

### [Pattern Rectangularity (EUV Exposure)]

A material for forming an organic underlayer film (“HM8006”, available from JSR Corporation) was applied on a 12-inch silicon wafer by spin-coating using a spin-coater (“CLEAN TRACK ACT12”, available from Tokyo Electron Ltd.), and thereafter heating was conducted at 250° C. for 60 sec to form an organic underlayer film having an average thickness of 100 nm. To the organic underlayer film was applied a composition for forming a silicon-containing film (“NFC SOG080” manufactured by JSR Corporation), heated at 220° C. for 60 sec, and then cooled at 23° C. for 30 sec. Thus, a silicon-containing film having an average thickness of 20 nm was formed. The composition prepared as described above was applied to the silicon-containing film formed as described above to form a resist underlayer film. The resist underlayer film formed as described above was heated at 250° C. for 90 seconds, and then cooled at 23° C. for 30 seconds, affording a resist underlayer film having an average thickness of 5 nm. To the resist underlayer film formed as described above was applied a resist composition (R-1), heated at 130° C. for 60 sec, and then cooled at 23° C. for 30 sec. Thus, a resist film having an average thickness of 50 nm was formed. Next, the resist film was irradiated with extreme ultraviolet rays using an EUV scanner (“TWINSCAN NXE:3300B”, available from ASML Co. (NA=0.3; Sigma=0.9; quadrupole illumination, with a 1: 1 line and space mask having a line width of 16 nm in terms of a dimension on wafer)). After the irradiation with the extreme ultraviolet rays, the substrate was heated at 110° C. for 60 sec, followed by cooling at 23° C. for 60 sec. Thereafter, development was performed by a paddle method using a 2.38% by mass aqueous tetramethylammonium hydroxide solution (20° C. to 25° C.), followed by washing with water and drying, thereby affording a substrate for evaluation having a resist pattern formed thereon. A scanning electron microscope (“SU8220” available from Hitachi High-Technologies Corporation) was used for length measurement and observation of the resist pattern of the substrate for evaluation. The pattern rectangularity was evaluated as “A” (good) when the cross-sectional shape of the pattern was rectangular, “B” (slightly good) when trailing was present in the cross section of the pattern, and “C” (poor) when a residue (defect) was present in the pattern.

TABLE 2

| | | Solvent | Pattern |
|---|---|---|---|
| | Composition | resistance | rectangularity |
| Example 1 | J-1 | B | A |
| Example 2 | J-2 | B | B |
| Example 3 | J-3 | B | A |
| Example 4 | J-4 | B | A |
| Example 5 | J-5 | A | A |
| Example 6 | J-6 | A | A |
| Example 7 | J-7 | A | A |
| Example 8 | J-8 | A | A |
| Example 9 | J-9 | A | A |
| Example 10 | J-10 | A | A |
| Example 11 | J-11 | A | A |
| Example 12 | J-12 | A | A |
| Example 13 | J-13 | A | A |
| Example 14 | J-14 | A | A |
| Example 15 | J-15 | A | A |
| Example 16 | J-16 | A | A |
| Example 17 | J-17 | A | A |
| Example 18 | J-18 | A | A |
| Example 19 | J-19 | A | A |
| Example 20 | J-20 | A | A |
| Example 21 | J-21 | A | A |
| Example 22 | J-22 | A | A |
| Example 23 | J-23 | A | A |
| Example 24 | J-24 | A | B |
| Example 25 | J-25 | A | B |
| Example 26 | J-26 | A | B |
| Example 27 | J-27 | A | A |
| Example 28 | J-28 | A | A |
| Example 29 | J-29 | A | A |
| Example 30 | J-30 | A | A |
| Example 31 | J-31 | A | A |
| Example 32 | J-32 | A | A |
| Example 33 | J-33 | A | A |
| Example 34 | J-34 | A | A |
| Example 35 | J-35 | A | A |
| Comparative | CJ-1 | C | C |
| Example 1 | | | |
| Comparative | CJ-2 | C | C |
| Example 2 | | | |
| Comparative | CJ-3 | C | C |
| Example 3 | | | |

### Evaluation

Using the compositions prepared as described above, the resist pattern rectangularity due to KrF exposure was evaluated by the following method. The evaluation results are given in the following Table 3.

### [Pattern Rectangularity (KrF Exposure)]

A material for forming an organic underlayer film (“HM8006”, available from JSR Corporation) was applied on a 12-inch silicon wafer by spin-coating using a spin-coater (“CLEAN TRACK ACT12”, available from Tokyo Electron Ltd.), and thereafter heating was conducted at 250° C. for 60 sec to form an organic underlayer film having an average thickness of 100 nm. To the organic underlayer film was applied a composition for forming a silicon-containing film (“NFC SOG800” manufactured by JSR Corporation), heated at 220° C. for 60 seconds, and then cooled at 23° C. for 30 seconds. Thus, a silicon-containing film having an average thickness of 20 nm was formed. The composition prepared as described above was applied to the silicon-containing film formed as described above to form a resist underlayer film. The resist underlayer film formed as described above was heated at 250° C. for 90 seconds, and then cooled at 23° C. for 30 seconds, affording a resist underlayer film having an average thickness of 5 nm. To the resist underlayer film formed was applied a resist composition (R-1), heated at 130° C. for 60 seconds, and then cooled at 23° C. for 30 seconds. Thus, a resist film having an average thickness of 50 nm was formed. Next, the resist film was irradiated with KrF rays using an KrF scanner (“NSR-S210D”, available from Nikon Corporation (NA=0.82; Sigma=inner 0.75, outer 0.91; Dipole illumination, with a 1:1 line and space mask having a line width of 130 nm in terms of a dimension on wafer)). After the irradiation with KrF rays, the substrate was heated at 110° C. for 60 seconds, followed by cooling at 23° C. for 60 seconds. Thereafter, development was performed by a paddle method using a 2.38% by mass aqueous tetramethylammonium hydroxide solution (20° C. to 25° C.), followed by washing with water and drying, thereby affording a substrate for evaluation having a resist pattern formed thereon. A scanning electron microscope (“CG5000” available from Hitachi High-Technologies Corporation) was used for length measurement and observation of the resist pattern of the substrate for evaluation. The pattern rectangularity was evaluated as “A” (good) when the cross-sectional shape of the pattern was rectangular, “B” (slightly good) when trailing was present in the cross section of the pattern, and “C” (poor) when a residue (defect) was present in the pattern.

TABLE 3

| | | Pattern |
|---|---|---|
| | Composition | rectangularity |
| Example 36 | J-1 | A |
| Example 37 | J-5 | A |
| Example 38 | J-9 | A |
| Example 39 | J-24 | B |
| Example 40 | J-27 | A |

### Evaluation

Using the compositions prepared as described above, the resist pattern rectangularity due to EB exposure was evaluated by the following method. The evaluation results are shown in Table 4.

### [Pattern Rectangularity (EB Exposure)]

A material for forming an organic underlayer film (“HM8006”, available from JSR Corporation) was applied on a 12-inch silicon wafer by spin-coating using a spin-coater (“CLEAN TRACK ACT12”, available from Tokyo Electron Ltd.), and thereafter heating was conducted at 250° C. for 60 sec to form an organic underlayer film having an average thickness of 100 nm. To the organic underlayer film was applied a composition for forming a silicon-containing film (“NFC SOG800” manufactured by JSR Corporation), heated at 220° C. for 60 seconds, and then cooled at 23° C. for 30 seconds. Thus, a silicon-containing film having an average thickness of 20 nm was formed. The composition prepared as described above was applied to the silicon-containing film formed as described above to form a resist underlayer film. The resist underlayer film formed as described above was heated at 250° C. for 60 seconds, and then cooled at 23° C. for 30 seconds, affording a resist underlayer film having an average thickness of 5 nm. To the resist underlayer film formed was applied a resist composition (R-1), heated at 130° C. for 60 seconds, and then cooled at 23° C. for 30 seconds. Thus, a resist film having an average thickness of 50 nm was formed. Next, the resist film was exposed using an EB scanner (electron beam lithography system (manufactured by ELIONIX Inc.; ELS-F150, current: 1 pA, voltage: 150 kV, pattern size: 200 nm). After the irradiation with an electron beam, the substrate was heated at 110° C. for 60 seconds, followed by cooling at 23° C. for 60 seconds. Thereafter, development was performed by a paddle method using a 2.38% by mass aqueous tetramethylammonium hydroxide solution (20° C. to 25° C.), followed by washing with water and drying, thereby affording a substrate for evaluation having a resist pattern formed thereon. A scanning electron microscope (“CG5000” available from Hitachi High-Technologies Corporation) was used for length measurement and observation of the resist pattern of the substrate for evaluation. The pattern rectangularity was evaluated as “A” (good) when the cross-sectional shape of the pattern was rectangular, “B” (slightly good) when trailing was present in the cross section of the pattern, and “C” (poor) when a residue (defect) was present in the pattern.

TABLE 4

| | | Pattern |
|---|---|---|
| | Composition | rectangularity |
| Example 41 | J-1 | A |
| Example 42 | J-5 | A |
| Example 43 | J-9 | A |
| Example 44 | J-24 | B |
| Example 45 | J-27 | A |

### Evaluation

Using the compositions prepared as described above, the resist pattern rectangularity due to EUV exposure was evaluated by the following method. The evaluation results are shown in Table 5.

### <Preparation of Resist Composition for EUV Exposure (R-2)>

The compound (S-1) to be used for the preparation of a resist composition for EUV exposure (R-2) was synthesized by the following procedure. In a reaction vessel, 6.5 parts bymass of isopropyltin trichloride was added while stirring 150 mL of a 0.5 N aqueous sodium hydroxide solution, and a reaction was carried out for 2 hours. The precipitate formed was collected by filtration, washed twice with 50 parts by mass of water, and then dried, affording a compound (S-1). The compound (S-1) was an oxidized hydroxide product of a hydrolysate of isopropyltin trichloride (the oxidized hydroxide product contained i-PrSnO_{(3/2-x/2)} (OH)ₓ (0<x<3) as a structural unit).

2 parts by mass of the compound (S-1) synthesized above and 98 parts by mass of propylene glycol monoethyl ether were mixed, and the resulting mixture was subjected to removal of residual water with activated 4 A molecular sieve, and then filtered through a filter having a pore size of 0.2 μm. Thus, a resist composition for EUV exposure (R-2) was prepared.

### [Pattern Rectangularity (EUV Exposure)]

A material for forming an organic underlayer film (“HM8006”, available from JSR Corporation) was applied on a 12-inch silicon wafer by spin-coating using a spin-coater (“CLEAN TRACK ACT12”, available from Tokyo Electron Ltd.), and thereafter heating was conducted at 250° C. for 60 sec to form an organic underlayer film having an average thickness of 100 nm. To the organic underlayer film was applied the composition for forming a resist underlayer film prepared above, heated at 220° C. for 60 sec, and then cooled at 23° C. for 30 sec. Thus, a resist underlayer film having an average thickness of 5 nm was formed. To the resist underlayer film was applied the resist composition for EUV exposure (R-2) by the spin coating method using the spin coater described above, and after a lapse of a prescribed time, heated at 90° C. for 60 sec, and then cooled at 23° C. for 30 sec. Thus, a resist film having an average thickness of 35 nm was formed. The resist film was exposed to light using an EUV scanner (“TWINSCAN NXE:3300B”, available from ASML Co. (NA=0.3; Sigma=0.9; quadrupole illumination, with a 1:1 line and space mask having a line width of 16 nm in terms of a dimension on wafer)). After the exposure, the substrate was heated at 110° C. for 60 sec, and subsequently cooled at 23° C. for 60 sec. Thereafter, development was performed by a paddle method using 2-heptanone (20 to 25° C.), and then dried, affording a substrate for evaluation with a resist pattern formed thereon. A scanning electron microscope (“CG-6300” available from Hitachi High-Tech Corporation) was used for length measurement and observation of the resist pattern of the substrate for evaluation. The pattern rectangularity was evaluated as “A” (good) when the cross-sectional shape of the pattern was rectangular, and “B” (poor) when trailing was present in the cross section of the pattern.

TABLE 5

| | | Pattern |
|---|---|---|
| | Composition | rectangularity |
| Example 46 | J-1 | A |
| Example 47 | J-5 | A |
| Example 48 | J-9 | A |
| Example 49 | J-24 | A |
| Example 50 | J-27 | A |

As can be seen from the results in Tables 2 to 5, the resist underlayer films formed from the compositions of Examples were superior in solvent resistance and pattern rectangularity to the resist underlayer films formed from the compositions of Comparative Examples.

By the method for manufacturing a semiconductor substrate of the present disclosure, it is possible to efficiently manufacture a semiconductor substrate because of using a composition for forming a resist underlayer film capable of forming a resist underlayer film superior in solvent resistance and pattern rectangularity. When the composition for forming a resist underlayer film of the present disclosure is used, a film superior in solvent resistance and pattern rectangularity can be formed. Therefore, they can suitably be used for, for example, producing semiconductor devices.

Obviously, numerous modifications and variations of the present invention(s) are possible in light of the above teachings. It is therefore to be understood that within the scope of the appended claims, the invention(s) may be practiced otherwise than as specifically described herein.

What is claimed is:

1. A method for manufacturing a semiconductor substrate, the method comprising:
applying a composition for forming a resist underlayer film directly or indirectly to a substrate to form a resist underlayer film;
applying a composition for forming a resist film to the resist underlayer film to form a resist film;
exposing the resist film to radiation; and
developing the exposed resist film,
wherein the composition for forming a resist underlayer film comprises:
a polymer having a sulfonic acid ester structure; and
a solvent.

2. The method according to claim 1, wherein
the polymer comprises at least one selected from the group consisting of a repeating unit represented by formula (1) and a repeating unit represented by formula (2): 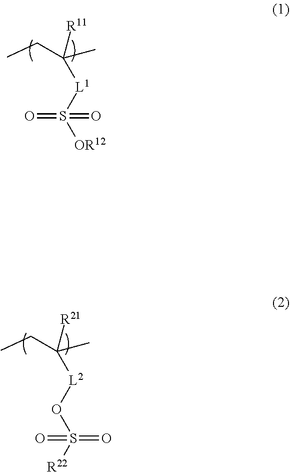
in the formulas (1) and (2), R¹¹ and R²¹ are each independently a hydrogen atom or a substituted or unsubstituted monovalent hydrocarbon group having 1 to 20 carbon atoms; R¹² and R²² are each independently a substituted or unsubstituted monovalent hydrocarbon group having 1 to 20 carbon atoms; L¹ is a single bond or a divalent linking group; and L² is a divalent linking group.

3. The method according to claim 1, further comprising before applying the composition for forming a resist film, heating the resist underlayer film at 200° C. or higher.

4. The method according to claim 1, wherein the radiation is a KrF excimer laser, an electron beam, or an extreme ultraviolet ray.

5. The method according to claim 1, wherein the resist underlayer film has a film thickness of 20 nm or less.

6. The method according to claim 1, wherein a developer to be used in developing the exposed resist film is a basic solution.

7. The method according to claim 1, further comprising forming a silicon-containing film directly or indirectly on the substrate before applying the composition for forming a resist underlayer film.

8. The method according to claim 2, wherein L¹ and L² are each independently a divalent group comprising a substituted or unsubstituted divalent aromatic hydrocarbon group.

9. The composition according to claim 2, wherein R¹² and R²² are each independently a monovalent hydrocarbon group having 1 to 20 carbon atoms and comprising a fluorine atom.

10. A composition comprising:
a polymer having a sulfonic acid ester structure; and
a solvent.

11. The composition according to claim 10, wherein
the polymer comprises at least one selected from the group consisting of a repeating unit represented by formula (1) and a repeating unit represented by formula (2): 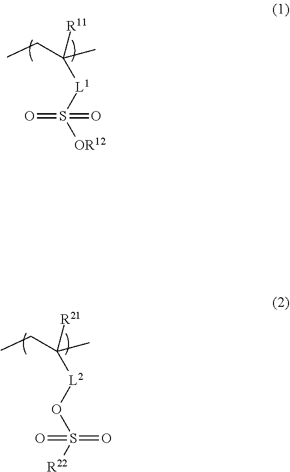
in the formulas (1) and (2), R¹¹ and R²¹ are each independently a hydrogen atom or a substituted or unsubstituted monovalent hydrocarbon group having 1 to 20 carbon atoms; R¹² and R²² are each independently a substituted or unsubstituted monovalent hydrocarbon group having 1 to 20 carbon atoms; L¹ is a single bond or a divalent linking group; and L² is a divalent linking group.

12. The composition according to claim 11, wherein L¹ and L² are each independently a divalent group comprising a substituted or unsubstituted divalent hydrocarbon group.

13. The composition according to claim 12, wherein the divalent hydrocarbon group in L¹ and L² is a divalent aromatic hydrocarbon group.

14. The composition according to claim 11, wherein R¹² and R²² are each independently a monovalent hydrocarbon group having 1 to 20 carbon atoms and comprising a fluorine atom.

15. The composition according to claim 11, wherein
the polymer has a repeating unit represented by formula (3) which is other than the formula (1) or (2): 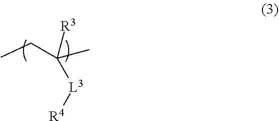
in the formula (3), R³ is a hydrogen atom or a substituted or unsubstituted monovalent hydrocarbon group having 1 to 20 carbon atoms; L³ is a single bond or a divalent linking group; and R⁴ is a monovalent organic group having 1 to 20 carbon atoms.

16. The composition according to claim 15, wherein L³ is a single bond, and R⁴ is a substituted or unsubstituted monovalent aromatic hydrocarbon group or a substituted or unsubstituted monovalent heterocyclic group.

17. The composition according to claim 11, wherein a content ratio of at least one selected from the group consisting of a repeating unit represented by the formula (1) and a repeating unit represented by the formula (2) accounting for in all repeating units constituting the polymer is 1 mol % or more and 70 mol % or less.

18. The composition according to claim 10, wherein the polymer is a block copolymer.

19. The composition according to claim 10, further comprising a crosslinking agent.

20. The composition according to claim 10, wherein a content ratio of the polymer accounting for in components other than the solvent in the composition is 10% by mass or more.
